(19) United States
(12) Patent Application Publication
(10) Pub. No.: US 2026/0253537 A1
(43) Pub. Date: Aug. 27, 2026

(54) DISPLAY DEVICE AND ELECTRONIC APPARATUS INCLUDING THE SAME

(71) Applicant: Samsung Display Co., Ltd., Yongin-si (KR)

(72) Inventors: Dae-Gwang JANG, Yongin-si (KR); Kuk-Hwan AHN, Yongin-si (KR); Kyungsu LEE, Yongin-si (KR); Seungjae LEE, Yongin-si (KR)

(73) Assignee: Samsung Display Co., Ltd., Yongin-si (KR)

(21) Appl. No.: 19/544,383

(22) Filed: Feb. 19, 2026

(30) Foreign Application Priority Data
Feb. 21, 2025 (KR) 10-2025-0023129

(51) Int. Cl. G09G 3/3225

(52) U.S. Cl. CPC G09G 3/3225; G09G 2300/0814; G09G 2320/0233; G09G 2320/0285; G09G 2330/021

(57) ABSTRACT

A display device including a first switching circuit activated by a first selecting signal, a second switching circuit activated by a second selecting signal, a display panel including a first pixel connected to a first data line and a first write scan line, the first data line connected to the first switching circuit, a second pixel connected to a second data line and the first write scan line, the second data line connected to the second switching circuit, a third pixel connected to the first data line and a second write scan line adjacent to the first write scan line, and a fourth pixel connected to the second data line and the second write scan line, and processing circuitry configured to compensate for a difference in luminance between the first and second pixels, the third and fourth pixels, the first and third pixels, and the second and fourth pixels.

### CROSS-REFERENCE TO RELATED APPLICATIONS

This application claims priority under 35 U.S.C. § 119 to Korean Patent Application No. 10-2025-0023129 filed on Feb. 21, 2025, in the Korean Intellectual Property Office, the disclosure of which is incorporated by reference herein in its entirety.

### BACKGROUND

Embodiments of the present disclosure described herein relate to a display device and an electronic apparatus including the same, and more particularly, relate to a display device, capable of improving image quality, and an electronic apparatus including the same.

Among display devices, an emissive-type display device displays an image by using a light emitting diode that generates a light through the recombination of electrons and holes. The emissive-type display device has a rapid response speed and is driven with lower power consumption.

The emissive-type display device includes a display panel in which pixels connected to data lines and scan lines are disposed. Each of the pixels generally includes a light emitting diode and a pixel circuit unit to control an amount of current flowing to the light emitting diode. The pixel circuit unit controls the amount of current flowing through the light emitting diode, in response to a data signal. In this case, a light having a specific luminance is emitted according to the amount of a current flowing through the light emitting diode.

### SUMMARY

Embodiments of the present disclosure provide a display device capable of preventing image quality from being degraded due to the difference in luminance (or reducing an amount of the degradation), and an electronic apparatus including the same.

According to embodiments of the present disclosure, a display device includes a driving controller configured to receive input image signals and compensate the input image signals to obtain compensated image signals, a selecting circuit including a first switching circuit activated in response to a first selecting signal and a second switching circuit activated in response to a second selecting signal, and a display panel configured to display an image, the display panel including a first pixel connected to a first data line and a first write scan line, the first data line being connected to the first switching circuit, a second pixel connected to a second data line and the first write scan line, the second data line being connected to the second switching circuit, a third pixel connected to the first data line and a second write scan line, the second write scan line being adjacent to the first write scan line, and a fourth pixel connected to the second data line and the second write scan line, the driving controller including processing circuitry configured to compensate for a difference in luminance between the first pixel and the second pixel, compensate for a difference in luminance between the third pixel and the fourth pixel, compensate for a difference in luminance between the first pixel and the third pixel, and compensate for a difference in luminance between the second pixel and the fourth pixel.

According to embodiments of the present disclosure, a display device includes a driving controller configured to receive input image signals and compensate the input image signals to obtain compensated image signals, a selecting circuit including a first switching circuit activated in response to a first selecting signal and a second switching circuit activated in response to a second selecting signal, and a display panel configured to display an image, the display panel including a first pixel connected to a first data line and a first write scan line, the first data line being connected to the first switching circuit, a second pixel connected to a second data line and the first write scan line, the second data line being connected to the second switching circuit, a third pixel connected to the first data line and a second write scan line, the second write scan line being adjacent to the first write scan line, and a fourth pixel connected to the second data line and the second write scan line, the driving controller including processing circuitry configured to configured to generate the compensated image signals using a difference in luminance between one reference pixel and remaining pixels, the one reference pixel being selected from among the first pixel, the second pixel, the third pixel and the fourth pixel, and the remaining pixels being among the first pixel, the second pixel, the third pixel and the fourth pixel.

According to embodiments of the present disclosure, an electronic apparatus includes a processor, a driving controller configured to receive input image signals from the processor and compensate the input image signals to obtain compensated image signals, a selecting circuit including a first switching circuit activated in response to a first selecting signal and a second switching circuit activated in response to a second selecting signal, and a display panel configured to display an image, the display panel including a first pixel connected to a first data line and a first write scan line, the first data line being connected to the first switching circuit, a second pixel connected to a second data line and the first write scan line, the second data line being connected to the second switching circuit, a third pixel connected to the first data line and a second write scan line, the second write scan line being adjacent to the first write scan line, and a fourth pixel connected to the second data line and the second write scan line, the driving controller including processing circuitry configured to compensate for a difference in luminance between the first pixel and the second pixel, compensate for a difference in luminance between the third pixel and the fourth pixel, compensate for a difference in luminance between the first pixel and the third pixel, and compensate for a difference in luminance between the second pixel and the fourth pixel.

The driving controller includes a first compensating circuit to compensate for difference in luminance between the first pixel and the second pixel, and difference in luminance between the third pixel and the fourth pixel, and a second compensating circuit to compensate for difference in luminance between the first pixel and the third pixel, and difference in luminance between the second pixel and the fourth pixel.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to embodiments of the present disclosure.

FIG. 2A is an exploded perspective view of a display device according to embodiments of the present disclosure.

FIG. 2B is a cross-sectional view of a display device according to embodiments of the present disclosure.

FIG. 3 is a block diagram of a display device according to embodiments of the present disclosure.

FIG. 4 is a circuit diagram of a pixel according to embodiments of the present disclosure.

FIG. 5 is a cross-sectional view illustrating a partial region of a display module illustrated in FIG. 2B.

FIG. 6 is a block diagram illustrating the connection among a data driver, a selecting circuit, and data lines according to embodiments of the present disclosure.

FIG. 7 is a waveform illustrating first and second selecting signals, first and second write scan signals, and a first compensating scan signal according to embodiments of the present disclosure.

FIG. 8 is a block diagram illustrating a driving controller according to embodiments of the present disclosure.

FIG. 9 is a block diagram illustrating a driving controller according to embodiments of the present disclosure.

FIG. 10 is a block diagram illustrating the connection among a data driver, a selecting circuit, and data lines according to embodiments of the present disclosure.

FIG. 11 is a waveform illustrating first to third selecting signals, first and second write scan signals, and a first compensating scan signal according to embodiments of the present disclosure.

FIG. 12 is a block diagram illustrating a driving controller according to embodiments of the present disclosure.

FIG. 13 is a block diagram illustrating a driving controller according to embodiments of the present disclosure.

FIG. 14 is a block diagram illustrating an electronic apparatus according to embodiments of the present disclosure.

FIG. 15 illustrates schematic views of an electronic apparatus according to embodiments.

### DETAILED DESCRIPTION

In the specification, the expression that a first component (or region, layer, or part) is “on”, “connected to”, or “coupled to” a second component refers to that the first component is directly on, connected to, or coupled to the second component or refers to that a third component is interposed therebetween.

The same (or a similar) reference numeral will be assigned to the same (or a similar) component. In addition, in drawings, thicknesses, proportions, and dimensions of components may be exaggerated to describe the technical features effectively. The term “and/or” includes any and all combinations of one or more of associated components.

Although the terms “first”, or “second” may be used to describe various components, the components should not be construed as being limited by the terms. The terms are only used to distinguish one component, part, region, layer, or portion from another component, part, region, layer, or portion. For example, without departing from the scope and spirit of the present disclosure, a first component, a first part, a first region, a first layer, or a first portion may be referred to as a second component, a second part, a second region, a second layer, or a second portion, respectively, and similarly, the second component, the second part, the second region, the second layer, or the second portion may be referred to as the first component, the first part, the first region, the first layer, or the first portion, respectively. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, operations, components, parts, or the combination thereof, but do not preclude the presence or addition of one or more other features, numbers, operations, components, components, and/or the combination thereof.

Unless defined otherwise, all terms (including technical terms and scientific terms) used in the specification have the same meaning as, or a similar meaning to, that commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to drawings.

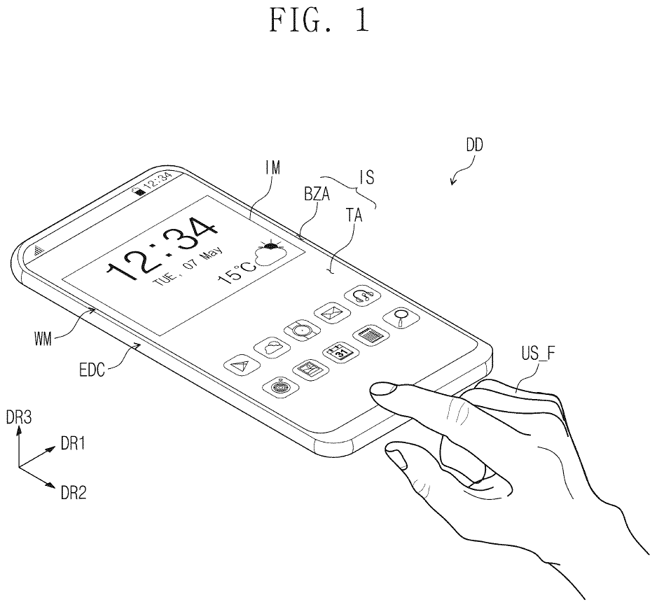

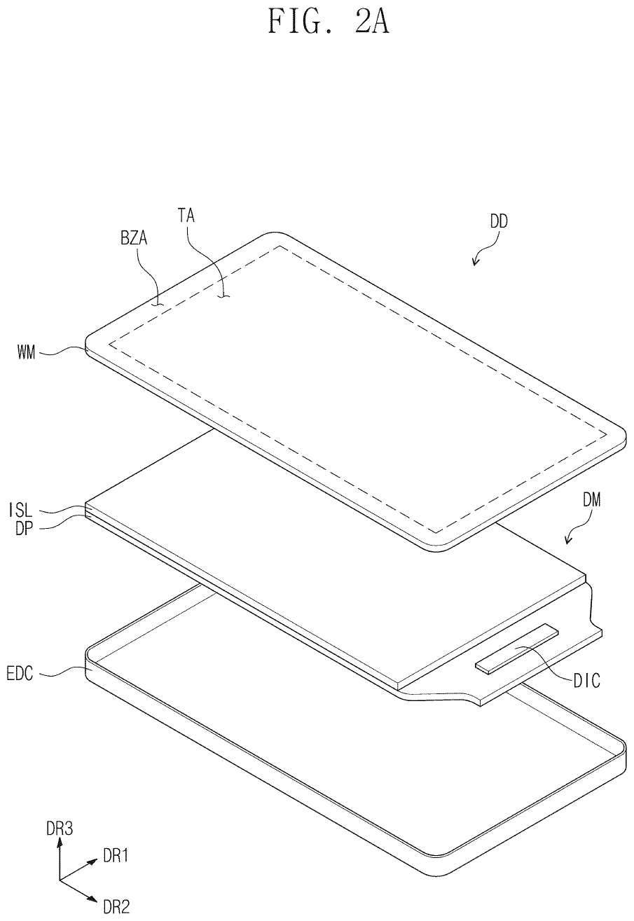

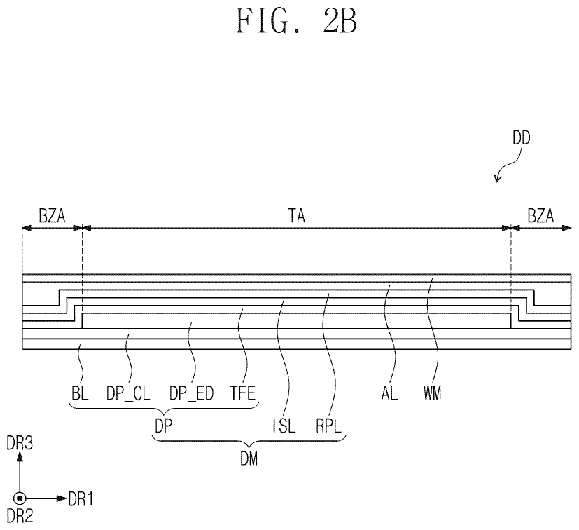

FIG. 1 is a perspective view illustrating a display device according to embodiments of the present disclosure, FIG. 2A is an exploded perspective view of a display device according to embodiments of the present disclosure, and FIG. 2B is a cross-sectional view of a display device according to embodiments of the present disclosure.

Referring to FIGS. 1, 2A and 2B, a display device DD according to embodiments of the present disclosure may have the shape of a rectangle having a shorter side parallel to a first direction DR1 and a longer side parallel to a second direction DR2 crossing the first direction DR1. However, the present disclosure is not limited thereto. For example, the display device DD may be implemented in various shapes such as a circle and a polygon.

The display device DD may be a device that is activated in response to an electrical signal. The display device DD may include various examples. For example, the display device DD may be applied to an electronic apparatus such as a smart watch, a tablet PC, a laptop computer, a smart television, etc.

Hereinafter, a direction normal (or substantially normal) to a plane defined by the first direction DR1 and the second direction DR2 is defined as a third direction DR3. In the specification, the meaning of “when viewed in a plan view” may refer to “when viewed in the third direction DR3”.

A top surface of the display device DD may be defined as a display surface IS, and may be parallel to a plane defined by the first direction DR1 and the second direction DR2. Images IM generated by the display device DD may be provided to the user through the display surface IS.

The display surface IS may be divided into a transmission region TA and a bezel region BZA. The transmission region TA may be a region for displaying the images IM. A user views the images IM through the transmission region TA According to the present example, the transmission region TA have vertexes in a rounded-rectangular shape. However, this is illustrated as one example. The transmission region TA may be implemented in various shapes and may not be limited to any one example.

The bezel region BZA is adjacent to the transmission region TA. The bezel region BZA may have specific color. The bezel region BZA may surround the transmission region TA. Accordingly, the shape of the transmission region TA may be defined substantially by the bezel region BZA. However, this is illustrated as an example. For example, the bezel region BZA may be only disposed adjacent only to one side of the transmission region TA or may be omitted.

The display device DD may sense an external input applied from the outside. The external input may include various types of inputs which are provided from the outside of the display device DD. For example, as well as a contact by a part of the human body such as the user's hand US_F or a contact by a separate device (for example, an active pen or a digitizer), the external input may include an external input (for example, hovering) that is applied in a state that the user's hand US_F approaches the display device DD or is adjacent to the display device DD within a specific distance. In addition, the external input may have various types such as force, pressure, a temperature, and a light.

The display device DD may include a window WM, a display module DM, and a housing EDC. According to embodiments, the window WM and the housing EDC are coupled to each other to form the outer appearance of the display device DD.

A front surface of the window WM defines the display surface IS of the display device DD. The window WM may include an optically transparent insulating material. For example, the window WM may include glass or plastic. The window WM may be implemented in a multi-layer structure or a single-layer structure. For example, the window WM may include a plurality of plastic films bonded to each other by an adhesive agent or may include a glass substrate and a plastic film bonded to each other by an adhesive agent.

The display module DM may include a display panel DP and/or an input sensing layer ISL. The display panel DP may display an image in response to an electrical signal, and the input sensing layer ISL may sense an external input applied from the outside. The external input may be provided in various forms.

The display panel DP according to embodiments of the present disclosure may be an emissive-type display panel, and the present disclosure is not particularly limited thereto. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot, or a quantum rod. In the following description, the display panel DP is an organic light emitting display panel.

Referring to FIG. 2B, the display panel DP includes a base layer BL, a circuit layer DP_CL, an element layer DP-ED, and/or an encapsulating layer TFE. The display panel DP according to the present disclosure may be a flexible display panel. However, the present disclosure is not limited thereto. For example, the display panel DP may be a foldable display panel, which is folded about to a folding axis, or a rigid display panel.

The base layer BL may include a synthetic resin layer. The synthetic resin layer may be a polyimide-based resin layer, and the material thereof is not particularly limited. Besides, the base layer BL may include a glass substrate, a metal substrate, or an organic/inorganic composite material substrate.

The circuit layer DP_CL is disposed on the base layer BL. The circuit layer DP_CL is interposed between the base layer BL and the element layer DP_ED. The circuit layer DP_CL includes at least one insulating layer and a circuit element. Hereinafter, the insulating layer included in the circuit layer DP_CL may be referred to as an intermediate insulating layer. The intermediate insulating layer includes at least one intermediate inorganic film and at least one intermediate organic film. The circuit element may include a pixel driving circuit included in each of a plurality of pixels to display an image and a sensor driving circuit included in each of a plurality of sensors to recognize external information. The external information may be biometrics information. According to embodiments of the present disclosure, the sensor may include a fingerprint recognizing sensor, a proximity sensor, an iris recognizing sensor, a blood pressure measuring sensor, an illuminance sensor, etc. In addition, the sensor may be an optical sensor to optically recognize biometrics information. The circuit layer DP_CL may further include signal lines connected to the pixel driving circuit and/or the sensor driving circuit.

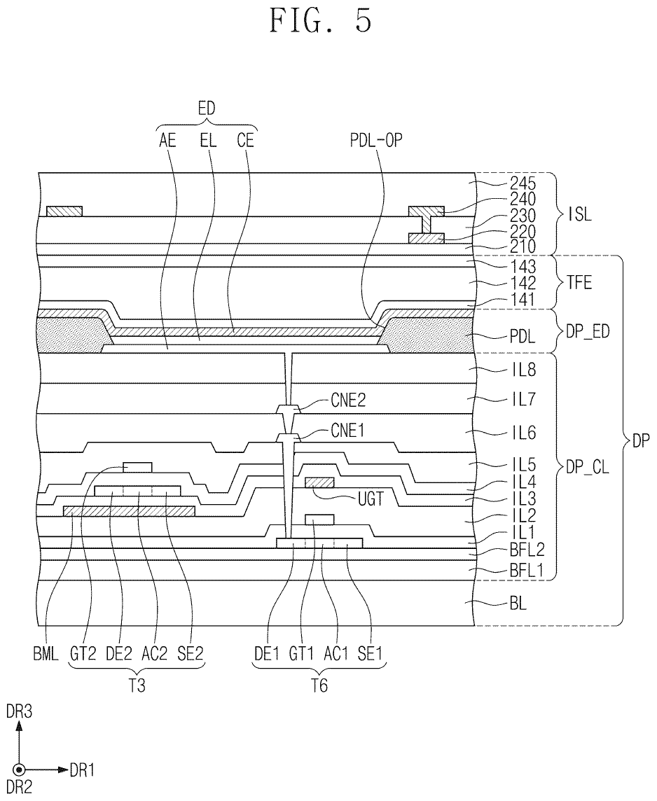

The element layer DP_ED may include a light emitting element included in each pixel and a light receiving element included in each of the sensors. According to embodiments of the present disclosure, the light receiving element may be a photodiode. The light receiving element may be a sensor to sense light reflected from the fingerprint of the user or a sensor reacting to light. The circuit layer DP_CL and the element layer DP_ED will be described in detail later with reference to FIG. 5.

The encapsulating layer TFE encapsulates the element layer DP_ED. The encapsulating layer TFE may include at least one organic film and at least one inorganic film. The inorganic film may include an inorganic material, and may protect the element layer DP_ED from moisture/oxygen. The inorganic layer may include a silicon nitride layer, a silicon oxy nitride layer, a silicon oxide layer, a titanium oxide layer, or an aluminum oxide layer, but the present is not particularly limited thereto. The organic layer may include an organic material, and may protect the element layer DP_ED from foreign substances such as dust particles.

The input sensing layer ISL may be formed on the display panel DP. The input sensing layer ISL may be directly disposed on the encapsulating layer TFE. According to embodiments of the present disclosure, the input sensing layer ISL may be formed on the display panel DP through subsequent processes. In other words, when the input sensing layer ISL is directly disposed on the display panel DP, an adhesive film is not disposed between the input sensing layer ISL and the encapsulating layer TFE. Alternatively, an adhesive film may be disposed between the input sensing layer ISL and the display panel DP. In this case, the input sensing layer ISL and the display panel DP are not fabricated through the subsequent processes. In other words, after fabricating the input sensing layer ISL through a process separate from that of the display panel DP, the input sensing layer ISL may be fixed on a top surface of the display panel DP through the adhesive film.

The input sensing layer ISL may sense an external input (for example, a touch of the user), may change the sensed input into a specific input signal, and may apply the input signal to the display panel DP. The input sensing layer ISL may include a plurality of sensing electrodes to sense an external input. The sensing electrodes may sense the external input through a capacitive manner. The display panel DP may receive an input signal applied from the input sensing layer ISL and may generate an image corresponding to the input signal.

The display module DM may further include an anti-reflective layer RPL. The anti-reflective layer RPL may reduce the reflectance of external light incident from the top surface of the display device DD toward the display panel DP. The external light may not be viewed to the user due to the anti-reflective layer RPL. According to embodiments of the present disclosure, the anti-reflective layer RPL may be disposed on the input sensing layer ISL. However, the present disclosure is not limited thereto. The anti-reflective layer RPL may be interposed between the display panel DP and the input sensing layer ISL. The anti-reflective layer RPL may include a plurality of color filters disposed to correspond to the pixels, respectively. The color filters may filter the external light having the same color as (or a similar color to) that of the pixels. In this case, the external light may not be viewed by the user. However, the present disclosure is not limited thereto. For example, the anti-reflective layer RPL may include a phase retarder and/or a polarizer, to reduce the reflectance of the external light.

The display device DD according to embodiments of the present disclosure may further include an adhesive layer AL. The window WM may be attached to the anti-reflective layer RPL through the adhesive layer AL. The adhesive layer AL may include an optical clear adhesive, an optically clear adhesive resin, or a pressure sensitive adhesive (PSA).

The display module DM may further include a driving chip DIC. According to embodiments of the present disclosure, the driving chip DIC may be mounted on the display panel DP while being adjacent to an end portion of the display panel DP. However, alternatively, the driving chip DIC may be mounted on a flexible circuit film coupled to one side of the display panel DP.

The housing EDC is coupled to the window WM. The housing EDC is coupled to the window WM to provide a specific inner space. The display module DM may be received in the inner space. The housing EDC may include a material having higher rigidity. For example, the housing EDC may include glass, plastic, or metal or may include a plurality of frames and/or a plurality of plates including a combination thereof. The housing EDC may stably protect the components of the display device DD, which are received in the inner space, from an external impact. Although not illustrated, a battery module may be interposed between the display module DM and the housing EDC to supply a power necessary (or otherwise, used) for the overall operation of the display device DD.

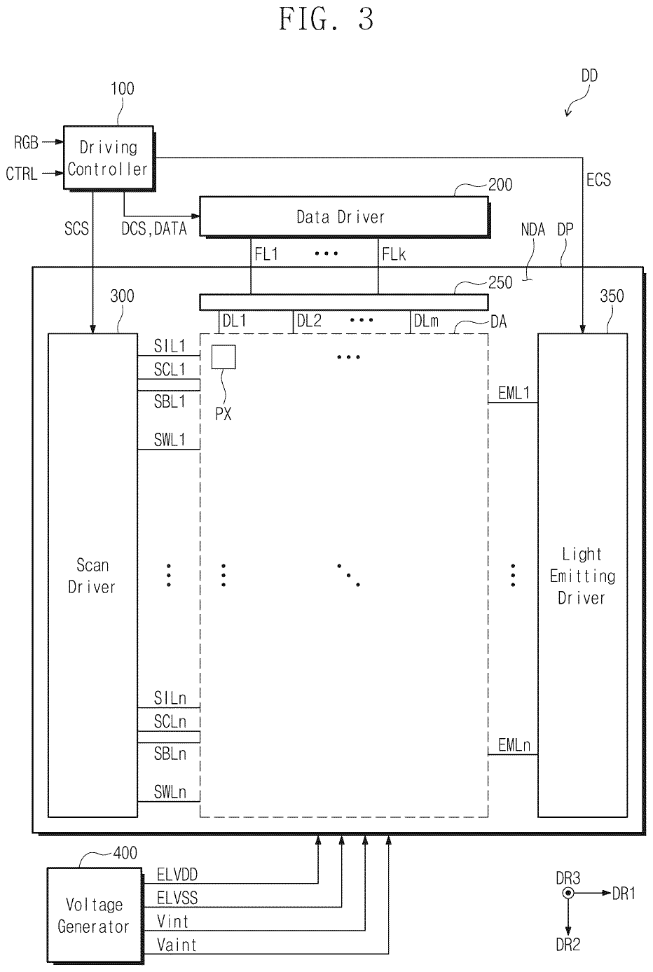

FIG. 3 is a block diagram of a display device according to embodiments of the present disclosure.

Referring to FIG. 3, the display device DD includes the display panel DP, a panel driver, and/or a driving controller 100. According to embodiments of the present disclosure, the panel driver includes a data driver 200, a selecting circuit 250, a scan driver 300, a light emitting driver 350, and/or a voltage generator 400.

The driving controller 100 receives an input image signal RGB and a control signal CTRL. The driving controller 100 generates a compensated image signal DATA by transforming a data format of the input image signal RGB to be matched to the specification for an interface with the data driver 200. The driving controller 100 outputs a first control signal SCS, a second control signal ECS, and a third control signal DCS.

The data driver 200 receives the third control signal DCS and the image data DATA (e.g., the compensated image signal DATA) from the driving controller 100. The data driver 200 converts the compensated image signal DATA into data signals, and outputs the data signals to a plurality of fan-out lines FL1 to FLk to be described later. The data signals refer to analog voltages corresponding to grayscale values of the image data DATA. According to embodiments of the present disclosure, the data driver 200 may be embedded in the driving chip DIC illustrated in FIG. 2A.

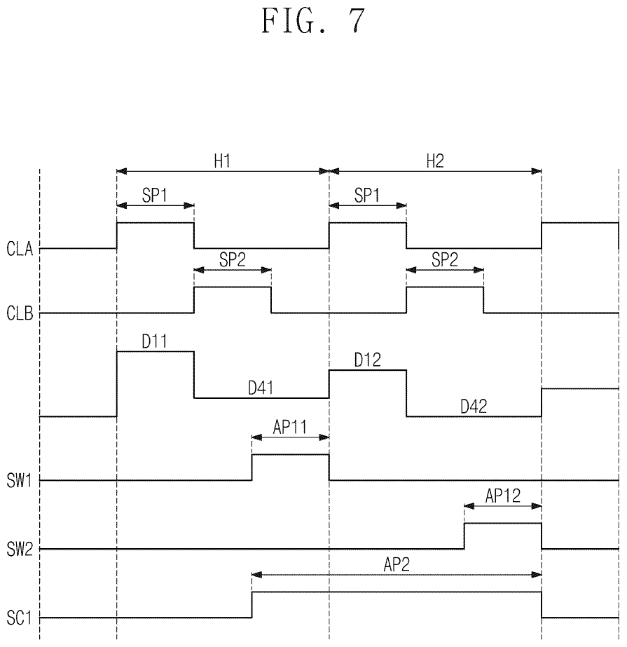

The data driver 200 may be connected to the selecting circuit 250 through the fan-out lines FL1 to FLk. The selecting circuit 250 may supply data signals to the data lines DL1 to DLm. The selecting circuit 250 may be interposed between the data lines DL1 to DLm and the data driver 200. In this case, ‘k’ and ‘m’ are integers equal to or greater than at least ‘1’, and ‘k’ may be smaller than ‘m’. According to embodiments of the present disclosure, the number (‘k’) of the fan-out lines FL1 to FLk may be ½/, ⅓, or ¼ of the number (‘m’) of the data lines DL1 to DLm. When the number (‘k’) of the fan-out lines FL1 to FLk is ½ of the number (‘m’) of the data lines, the data lines DL1 to DLm may be divided into two groups (that is, a first data line group and a second data line group). The selecting circuit 250 electrically connects some (for example, the first data line group) of the data lines DL1 to DLm to the data driver 200 during a first selecting period SP1 (see FIG. 7), and electrically connects some (for example, the second data line group) of the data lines DL1 to DLm to the data driver 200 during a second selecting period SP2 (see FIG. 7).

The scan driver 300 receives the first control signal SCS from the driving controller 100. The scan driver 300 may output scan signals to scan lines in response to the first control signal SCS.

The voltage generator 400 generates voltages necessary (or otherwise, used) for an operation of the display panel DP. According to embodiments, the voltage generator 400 generates a first driving voltage ELVDD, a second driving voltage ELVSS, a first initializing voltage Vint, and a second initializing voltage Vaint.

The display panel DP may include a display region DA corresponding to the transmission region TA (illustrated in FIG. 1) and a non-display region NDA corresponding to the bezel region BZA (illustrated in FIG. 1).

The display panel DP may include a plurality of pixels PX disposed in the display region DA. The display panel DP further includes initializing scan lines SIL1 to SILn, compensating scan lines SCL1 to SCLn, write scan lines SWL1 to SWLn, black scan lines SBL1 to SBLn, emission control lines EML1 to EMLn, and data lines DL1 to DLm. The initializing scan lines SIL1 to SILn, the compensating scan lines SCL1 to SCLn, the write scan lines SWL1 to SWn, the black scan lines SBL1 to SBLn, and the emission control lines EML1 to EMLn extend in the first direction DR1. The initializing scan lines SIL1 to SILn, the compensating scan lines SCL1 to SCLn, the write scan lines SWL1 to SWLn, the black scan lines SBL1 to SBLn, and the emission control lines EML1 to EMLn are arranged to be spaced from each other in the second direction DR2. The data lines DL1 to DLm extend in the second direction DR2, and are arranged to be spaced from each other in the first direction DR1. In this case, “m” and “n” are natural numbers equal to or greater than ‘1’.

The plurality of pixels PX are electrically connected to the initializing scan lines SIL1 to SILn, the compensating scan lines SCL1 to SCLn, the write scan lines SWL1 to SWLn, the black scan lines SBL1 to SBLn, the emission control lines EML1 to EMLn, and the data lines DL1 to DLm. For example, each of the plurality of pixels PX may be electrically connected to four scan lines. However, the number of scan lines connected to each pixel PX is not limited thereto and may be changed.

According to embodiments of the present disclosure, the selecting circuit 250 may be disposed in the non-display region NDA of the display panel DP. In particular, the selecting circuit 250 may be formed in the non-display region NDA through a process the same as (or similar to) a process for the pixel circuit unit of each pixel PX. The data lines DL1 to DLm may be selectively driven using the selecting circuit 250, thereby wholly reducing the number of channels of the data driver 200 and the number of the fan-out lines FL1 to FLk.

The scan driver 300 may be disposed in the non-display region NDA of the display panel DP. The scan driver 300 receives the first control signal SCS from the driving controller 100. In response to the first control signal SCS, the scan driver 300 outputs initializing scan signals to the initializing scan lines SIL1 to SILn and may output compensating scan signals to the compensating scan lines SCL1 to SCLn. In addition, in response to the first control signal SCS, the scan driver 300 may output write scan signals to the write scan lines SWL1 to SWLn and may output black scan signals to the black scan lines SBL1 to SBLn. Alternatively, the scan driver 300 may include a first scan driver and a second scan driver. The first scan driver may output write scan signals, and the second scan driver may output compensating scan signals and initializing scan signals. The first and second scan drivers may be disposed to be adjacent to opposite side portions of the display region DA, respectively.

The light emitting driver 350 may be disposed in the non-display region NDA of the display panel DP. The light emitting driver 350 receives the second control signal ECS from the driving controller 100. The light emitting driver 350 may output emission control signals to the emission control lines EML1 to EMLn, in response to the second control signal ECS. Alternatively, the scan driver 300 may be connected to the emission control lines EML1 to EMLn. In this case, the light emitting driver 350 may be omitted, and the scan driver 300 may output emission control signals to the emission control lines EML1 to EMLn.

According to embodiments of the present disclosure, the selecting circuit 250, the scan driver 300, and the light emitting driver 350 may be formed through a thin film process the same as (or similar to) a thin film process of the pixel circuit unit of each pixel PX. The selecting circuit 250, the scan driver 300, and the light emitting driver 350 may include transistors.

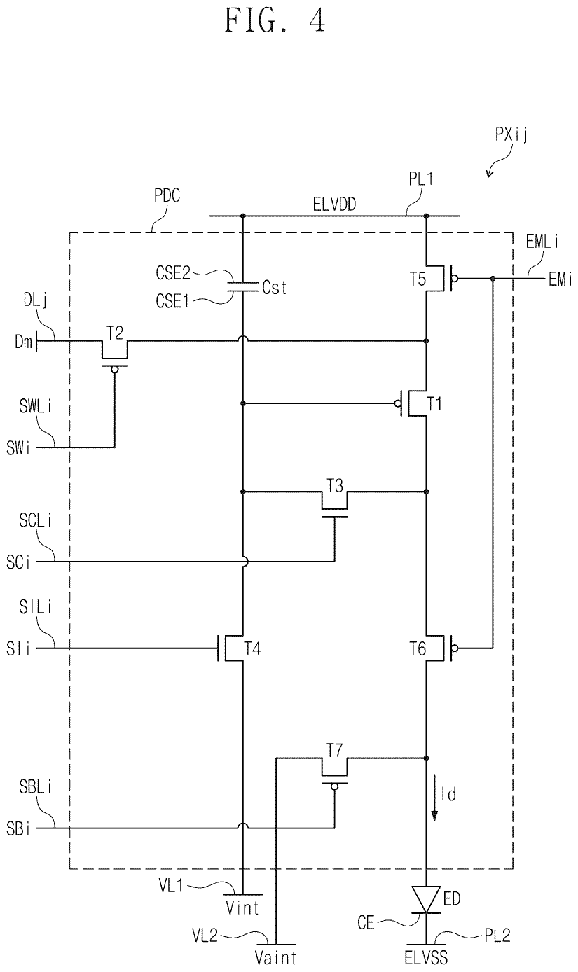

FIG. 4 is a circuit diagram illustrating a pixel according to embodiments of the present disclosure. FIG. 4 illustrates an equivalent circuit diagram of the pixel PXij of the plurality of pixels PX illustrated in FIG. 3.

Referring to FIG. 4, the pixel PXij may include a light emitting element ED and a pixel driving circuit PDC.

The pixel driving circuit PDC may include a plurality of transistors T1 to T7 and a storage capacitor Cst. The pixel driving circuit PDC may be electrically connected to the signal lines SWLi, SCLi, SILi, SBLi, EMLi, and DLj, a first initializing voltage line VL1, a second initializing voltage line VL2 (or an anode initializing voltage line), and a first power line PL1. According to embodiments, at least one of the above-described lines, for example, the first power line PL1, may be commonly connected to the pixel driving circuits PDC of the adjacent pixels PX.

The plurality of transistors T1 to T7 may include a driving transistor T1 (or a first transistor), a switching transistor T2 (a second transistor), a compensating transistor T3 (or a third transistor), a first initializing transistor T4 (or a fourth transistor), a first control transistor T5 (or a fifth transistor), a second control transistor T6 (or a sixth transistor), and a second initializing transistor T7 (or a seventh transistor).

The light emitting element ED may include a first electrode (e.g., an anode electrode) and a second electrode CE (e.g., a cathode electrode). The first electrode of the light emitting element ED may be connected to the driving transistor T1 through the second control transistor T6 to receive a driving current Id, and the second electrode CE of the light emitting element ED may be connected to a second power line PL2 to receive a second driving voltage ELVSS. The light emitting element ED may generate a light having a luminance corresponding to the driving current Id. According to embodiments, the second electrode CE of the light emitting element ED may serve as a common electrode commonly connected to the pixels PX.

Some of the plurality of transistors T1 to T7 may be provided in the form of an n-channel MOSFET (NMOS), and remaining transistors of the plurality of transistors T1 to T7 may be provided in the form of a p-channel MOSFET (PMOS). For example, the compensating transistor T3 and the first initializing transistor T4 of the plurality of transistors T1 to T7 may be provided in the form of the n-channel MOSFET (NMOS), and remaining transistors of the plurality of transistors T1 to T7 may be provided in the form of a p-channel MOSFET (PMOS).

According to embodiments, each of the compensating transistor T3, the first initializing transistor T4, and the second initializing transistor T7 of the plurality of transistors T1 to T7 is provided in the form of an NMOS, and each of remaining transistors of the plurality of transistors T1 to T7 may be provided in the form of a PMOS. Alternatively, only one of the plurality of transistors T1 to T7 may be provided in the form of an NMOS, and remaining transistors of the plurality of transistors T1 to T7 may be provided in the form of PMOSs. Alternatively, all transistors of the plurality of transistors T1 to T7 may be provided in the form of an NMOS, or a PMOS.

The signal lines includes the write scan line SWLi for receiving a write scan signal SWi, the compensating scan line SCLi for receiving a compensating scan signal SCi, the initializing scan line SILi for providing an initializing scan signal SIi to the first initializing transistor T4, the emission control line EMLi for providing an emission control signal EMi to the first control transistor T5 and the second control transistor T6, and the black scan line SBLi for transmitting a black scan signal SBi to the second initializing transistor T7. The signal lines may further include the data line DLj for transmitting a data signal Dm while crossing the scan lines SWLi, SCLi, SILi, and SBLi.

The first power line PL1 may apply the first driving voltage ELVDD to the driving transistor T1, and the first initializing voltage line VL1 may apply the first initializing voltage Vint to a gate electrode of the driving transistor T1 and the first electrode of the light emitting element ED.

The gate electrode of the driving transistor T1 may be connected to the storage capacitor Cst, the first electrode (or a source electrode) of the driving transistor T1 may be connected to the first power line PL1 through the first control transistor T5, and the second electrode (or a drain electrode) of the driving transistor T1 may be electrically connected to the first electrode of the light emitting element ED through the second control transistor T6. The driving transistor T1 may receive the data signal Dm and supply the driving current Id to the light emitting element ED, depending on the switching operation of the switching transistor T2.

The gate electrode of the switching transistor T2 may be connected to the write scan line SWLi, the first electrode of the switching transistor T2 may be connected to the data line DLj, and the second electrode of the switching transistor T2 may be connected to the first electrode of the driving transistor T1. The switching transistor T2 may be turned on in response to the write scan signal SWi received through the write scan line SWLi to perform a switching operation for applying the data signal Dm of the data line DLj to the first electrode of the driving transistor T1.

The gate electrode of the compensating transistor T3 is connected to the compensating scan line SCLi. The first electrode of the compensating transistor T3 may be connected to the second electrode of the driving transistor T1, and the second electrode of the compensating transistor T3 may be connected to a first electrode CSE1 of the storage capacitor Cst and the gate electrode of the driving transistor T1. The compensating transistor T3 may be turned on in response to the compensating scan signal SCi received through the compensating scan line SCLi to electrically connect the gate electrode and the second electrode of the driving transistor T1 such that the driving transistor T1 is diode-connected.

The gate electrode of the first initializing transistor T4 may be connected to the initializing scan line SILi. A first electrode of the first initializing transistor T4 may be connected to the first initializing voltage line VL1, and a second electrode of the first initializing transistor T4 may be connected to the first electrode CSE1 of the storage capacitor Cst, the second electrode of the compensating transistor T3, and the gate electrode of the driving transistor T1. The first initializing transistor T4 is turned on in response to the initializing scan signal SIi received through the initializing scan line SILi to apply the first initializing voltage Vint to the gate electrode of the driving transistor T1. Accordingly, an initializing operation may be performed to initialize the gate electrode of the driving transistor T1 with the first initializing voltage Vint.

The gate electrode of the first control transistor T5 may be connected to the emission control line EMLi, the first electrode of the first control transistor T5 may be connected to the first power line PL1, and the second electrode of the first control transistor T5 may be connected to the first electrode of the driving transistor T1 and the second electrode of the switching transistor T2.

The gate electrode of the second control transistor T6 is connected to the emission control line EMLi, and the first electrode of the second control transistor T6 is connected to the second electrode of the driving transistor T1 and the first electrode of the compensating transistor T3. The second electrode of the second control transistor T6 is connected to the first electrode of the light emitting element ED.

The first control transistor T5 and the second control transistor T6 are simultaneously (or contemporaneously) turned on in response to the emission control signal EMi received through the emission control line EMLi such that the first driving voltage ELVDD is applied to the light emitting element ED. Accordingly, the driving current Id may flow through the light emitting element ED. Alternatively, the first control transistor T5 and the second control transistor T6 may be connected to mutually different light emission control lines, respectively.

The gate electrode of the second initializing transistor T7 may be connected to the black scan line SBLi, and the first electrode of the second initializing transistor T7 may be connected to the second initializing voltage line VL2 to receive the second initializing voltage Vaint. The second electrode of the second initializing transistor T7 is connected to the second electrode of the second control transistor T6 and the first electrode of the light emitting element ED. The second initializing transistor T7 is turned on in response to the black scan signal SBi received through the black scan line SBLi such that the first electrode of the light emitting element ED is initialized with the second initializing voltage Vaint.

According to embodiments, the second initializing transistor T7 may be connected to the emission control line EMLi and be driven in response to emission control signal EMi. The positions of the first and second electrodes of each transistor may be changed, depending on the type (p-type or n-type) of the transistor.

The storage capacitor Cst may include the first electrode CSE1 and a second electrode CSE2. The first electrode CSE1 of the storage capacitor Cst is connected to the gate electrode of the driving transistor T1, and the second electrode CSE2 of the storage capacitor Cst is connected to the first power line PL1. The storage capacitor Cst may store charges corresponding to the difference between a potential of the gate electrode of the driving transistor T1 and the first driving voltage ELVDD.

Hereinafter, an operation of each pixel PX according to embodiments will be described in detail.

During an initialization period, when the initializing scan signal Sli is provided through the initializing scan line SILi, the first initializing transistor T4 is turned on, in response to the initializing scan signal Sli, and the driving transistor T1 is initialized with the first initializing voltage Vint received from the first initializing voltage line VL1.

During a data programming period, when the write scan signal SWi and the compensating scan signal SCi are provided through the write scan line SWLi and the compensating scan line SCLi, the switching transistor T2 and the compensating transistor T3 are turned on, in response to the write scan signal SWi and the compensating scan signal SCi. In this case, the driving transistor T1 is diode-connected by the turned-on compensating transistor T3, and is biased in the forward direction.

Then, the gate electrode of the driving transistor T1 is applied with a compensating voltage (Dm+Vth; Vth is a negative, (−) value) which is obtained by subtracting a threshold voltage (Vth) of the driving transistor T1 from the data signal Dm supplied through the data line DLj.

The first driving voltage ELVDD and the compensating voltage “Dm+Vth” are applied to opposite terminals of the storage capacitor Cst, and charges corresponding to the voltage difference between the opposite terminals of the storage capacitor Cst are stored in the storage capacitor Cst.

During an emission period, the first control transistor T5 and the second control transistor T6 are turned on in response to the emission control signal EMi supplied through the emission control line EMLi. The driving current Id is generated to correspond to the difference between the voltage at the gate electrode of the driving transistor T1 and the first driving voltage ELVDD, and is supplied to the light emitting element ED through the second control transistor T6.

According to embodiments, at least one of the plurality of transistors T1 to T7 includes a semiconductor layer including an oxide, and remaining transistors of the plurality of the transistors T1 to T7 include a semiconductor layer including silicon. In detail, the driving transistor T1 directly exerting an influence on the luminance of the display device may be configured to include a semiconductor layer including polycrystalline silicon having higher reliability, thereby implementing a higher-resolution display device. However, since the oxide semiconductor has higher carrier mobility and lower leakage current, the voltage drop is not significant even if the driving time is longer. In other words, even during lower-frequency driving, the color of the image is not significantly changed by the voltage drop. Accordingly, the lower-frequency driving is possible.

As described above, the oxide semiconductor shows a weaker leakage current. Accordingly, as at least one of the compensating transistor T3 and/or the first initializing transistor T4 employs the oxide semiconductor, the leakage current is prevented from flowing into the gate electrode of the driving transistor T1 (or reduced) while reducing power consumption.

FIG. 5 is a cross-sectional view illustrating a partial region of the display module illustrated.

Referring to FIG. 5, the display module DM may include the display panel DP and the input sensing layer ISL directly disposed on the display panel DP The display panel DP may include a base layer BL, a circuit layer DP_CL, the element layer DP_ED, and the encapsulating layer TFE.

The base layer BL may be a member to provide a base surface for disposing the circuit layer DP_CL. The circuit layer DP_CL may be disposed on the base layer BL. The circuit layer DP_CL may include an insulating layer, a semiconductor pattern, a conductive pattern, and a signal line. The insulating layer, the semiconductor layer, and the conductive layer are formed on the base layer BL through a coating scheme or a deposition scheme. Thereafter, the insulating layer, the semiconductor layer, and the conductive layer may be selectively patterned through a plurality of photolithography processes. Thereafter, the semiconductor pattern, the conductive pattern, and the signal line included in the circuit layer DP_CL may be formed.

At least one inorganic layer is formed on the top surface of the base layer BL. According to embodiments, the display panel DP is illustrated as including two buffer layers BFL1 and BFL2 (e.g., first and second buffer layers). The first and second buffer layers BFL1 and BFL2 may improve coupling force between the base layer BL and the semiconductor pattern. The first and second buffer layers BFL1 and BFL2 may include a silicon oxide layer and a silicon nitride layer, and the silicon oxide layer and the silicon nitride layer may be alternately stacked.

The first semiconductor pattern may be disposed on the second buffer layer BFL2. The first semiconductor pattern may include polysilicon. However, the present disclosure is not limited thereto. For example, the semiconductor pattern may include amorphous silicon or a metal oxide.

FIG. 5 illustrates only a portion of a first semiconductor pattern, and the first semiconductor pattern may be further disposed in another region. The first semiconductor pattern may be arranged in a specific rule over (or a specific layout among) the pixels. The first semiconductor pattern may have different electrical properties depending on whether the first semiconductor pattern is doped. The first semiconductor pattern may include a first region having higher conductivity and a second region having lower conductivity. The first region may be doped with an N-type dopant or a P-type dopant. A P-type transistor includes a doping region doped with the P-type dopants. The second region may be a non-doped region or may be doped at a lower concentration than that of the first region.

The first region may have conductivity greater than that of the second region, and may actually serve as an electrode or a signal line. The second region may actually correspond to an active region (or channel region) of a transistor. In other words, a portion of the first semiconductor pattern may be the channel region of the transistor, and another portion of the semiconductor pattern may be a source region or a drain region of the transistor.

FIG. 5 illustrates the light emitting element ED, and the compensating transistor T3 and the second control transistor T6 of the pixel driving circuit PDC.

A source region SE1, an active region AC1, and a drain region DE1 of the second control transistor T6 may be formed from the first semiconductor pattern. The source region SE1 and the drain region DE1 may extend in directions opposite to each other from the channel region AC1, when viewed in a cross-sectional view.

A first insulating layer IL1 may be disposed on the second buffer layer BFL2. The first insulating layer IL1 may be overlapped with a plurality of pixels in common and may cover the first semiconductor pattern. The first insulating layer IL1 may be an inorganic layer and/or an organic layer, and may have a single-layer structure or a multi-layer structure. The first insulating layer IL1 may include at least one of an aluminum oxide, a titanium oxide, a silicon oxide, a silicon nitride, a silicon oxynitride, a zirconium oxide, or a hafnium oxide. According to the present example, the first insulating layer IL1 may be a silicon oxide layer having a single-layer structure. In addition to the first insulating layer IL1, the insulating layer of the circuit layer DP_CL, which is to be described below, may be an inorganic layer and/or an organic layer, and may have a single-layer structure or a multi-layer structure. The inorganic layer may include at least one of the above-described materials, and the present disclosure is not limited thereto.

A gate electrode GT1 of the second control transistor T6 is disposed on the first insulating layer IL1. The gate electrode GT1 may be a portion of a metal pattern. The gate electrode GT1 may be overlapped with the channel region AC1. The gate electrode GT1 may function as a mask in a process of doping the first semiconductor pattern.

A second insulating layer IL2 may be disposed on the first insulating layer IL1 and may cover the gate electrode GT1. The second insulating layer IL2 may be commonly overlapped with the pixels. The second insulating layer IL2 may be an inorganic layer and/or an organic layer, and may have a single-layer structure or a multi-layer structure. According to embodiments, the second insulating layer IL2 may be a silicon oxide layer having a single-layer structure.

An upper gate electrode UGT of the second control transistor T6 is disposed on the second insulating layer IL2. The upper gate electrode UGT may be a portion of a metal pattern. The upper gate electrode UGT is overlapped with the gate electrode GT1 of the second control transistor T6.

A third insulating layer IL3 may be disposed on the second insulating layer IL2. The third insulating layer IL3 may be commonly overlapped with the plurality of pixels to cover the upper gate electrode UGT. The third insulating layer IL3 may have a single-layer structure or a multi-layer structure. According to embodiments, the third insulating layer IL3 may have a multi-layer structure including a silicon oxide layer and a silicon nitride layer. A rear metal layer BML may be interposed between the second insulating layer IL2 and the third insulating layer IL3. The rear metal layer BML may receive a constant voltage or a signal. The rear metal layer BML may be disposed on the same layer as (or a similar layer to) the upper gate electrode UGT of the second control transistor T6.

The second semiconductor pattern may be disposed on the third insulating layer IL3. The second semiconductor pattern may include an oxide semiconductor. The oxide semiconductor may include a plurality of regions that are distinguished depending on whether the metal oxide is reduced. A region (hereinafter referred to as a “reduction region”), in which the metal oxide is reduced, has higher conductivity than a region (hereinafter referred to as a “non-reduction region”) in which the metal oxide is not reduced. The reduction region actually functions as a source region/drain region of the transistor or a signal line. The non-reduction region actually corresponds to an active region (or a channel region) of a transistor. In other words, a portion of the second semiconductor pattern may be a panel region of a transistor, another portion of the second semiconductor pattern may be a source region or a drain region of the transistor, and still another portion may be a signal transmission region.

A source region SE2, a channel region AC2, and a drain region DE2 of the compensating transistor T3 may be formed from the second semiconductor pattern. The source region SE2 and the drain region DE2 may extend in directions opposite to each other from the channel region AC2, when viewed in a cross-sectional view.

A fourth insulating layer IL4 may be disposed on the third insulating layer IL3. The fourth insulating layer IL4 may be commonly overlapped with a plurality of pixels and may cover the second semiconductor pattern. The fourth insulating layer IL4 may include at least one of an aluminum oxide, a titanium oxide, a silicon oxide, a silicon nitride, a silicon oxynitride, a zirconium oxide, or a hafnium oxide.

A gate electrode GT2 of the compensating transistor T3 is disposed on the fourth insulating layer IL4. The gate electrode GT2 may be a portion of a metal pattern. The gate electrode GT2 may be overlapped with the channel region AC2. The gate electrode GT2 may function as a mask in a process of doping the second semiconductor pattern.

A fifth insulating layer IL5 may be disposed on the fourth insulating layer IL4 and may cover the gate electrode GT2. The fifth insulating layer IL5 may be an inorganic layer and/or an organic layer, and may have a single-layer structure or a multi-layer structure.

A first connection electrode CNE1 may be disposed on the fifth insulating layer IL5. The first connection electrode CNE1 may be connected to the drain region DE1 of the second control transistor T6 through a contact hole formed through the first to fifth insulating layers IL1, IL2, IL3, IL4, and IL5.

A sixth insulating layer IL6 may be disposed on the fifth insulating layer IL5. A second connection electrode CNE2 may be disposed on the sixth insulating layer IL6. The second connection electrode CNE2 may be connected to the first connection electrode CNE1 through a contact hole formed through the sixth insulating layer IL6.

According to embodiments of the present disclosure, the second power line PL2 (refer to FIG. 4) may be disposed on the sixth insulating layer IL6. In other words, the second power line PL2 may be disposed on a layer the same as (or similar to) a layer for the second connection electrode CNE2. However, the present disclosure is not limited thereto. Alternatively, the second power line PL2 may be disposed on a layer the same as (or similar to) a layer for the first connection electrode CNE1.

A seventh insulating layer IL7 may be disposed on the sixth insulating layer IL6 and may cover the second connection electrode CNE2 and the second power line PL2. An eighth insulating layer IL8 may be disposed on the seventh insulating layer IL7.

Each of the sixth insulating layer IL6, the seventh insulating layer IL7, and the eighth insulating layer IL8 may be an organic layer. For example, each of the sixth insulating layer IL6, the seventh insulating layer IL7, and the eighth insulating layer IL8 may include general purpose polymers such as benzocyclobutene (BCB), polyimide, hexamethyldisiloxane (HMDSO), polymethylmethacrylate (PMMA), or polystyrene (PS); a polymer derivative having a phenolic group; an acrylic polymer; an imide-based polymer; an acryl ether polymer; an amide-based polymer; a fluorine-based polymer; a p-xylene-based polymer; a vinyl alcohol-based polymer; or the blend thereof.

The element layer DP_ED including the light emitting element ED may be disposed on the circuit layer DP_CL. The light emitting element ED may include a first electrode AE, a light emitting layer EL, and the second electrode CE. The second electrode CE may be connected to the pixels PX (see FIG. 3) to be provided in common.

The first electrode AE may be disposed on the eighth insulating layer IL8. The first electrode AE may be a (semi) transmissive electrode or a reflective electrode. According to embodiments, the first electrode AE may include a reflective layer formed of Ag, Mg, Al, Pt, Pd, Au, Ni, Nd, Ir, Cr, or a compound thereof, and a transparent electrode layer or a translucent electrode layer formed on the reflective layer. The transparent or semi-transparent electrode layer may include at least one selected from a group including indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode AE may include ITO/Ag/ITO.

A pixel defining layer PDL may be disposed on the eighth insulating layer IL8. The pixel defining layer PDL may have a property of absorbing a light. For example, the pixel defining layer PDL may have a black color. The pixel defining layer PDL may include a black coloring agent. The black coloring agent may include a black dye, and a black pigment. The black coloring agent may include carbon black a metal, such as chromium, or an oxide thereof.

The pixel defining layer PDL may cover a portion of the first electrode AE. For example, a pixel opening PDL-OP exposing a portion of the first electrode AE may be defined in the pixel defining layer PDL. A region, which overlaps the pixel opening PDL-OP in the display panel DP may be defined as a light emitting region EA, and the remaining region of the display panel DP may be defined as a non-light emitting region NEA. The light emitting element ED may be provided to correspond to the light emitting region EA.

The light emitting layer EL may be disposed on the first electrode AE. According to the present example, the light emitting layer EL may output a light of at least one color of blue, red, and/or green.

The second electrode CE may be disposed on the light emitting layer EL. The second electrode CE may be commonly formed with respect to a plurality of pixels PX by using an open mask.

A hole control layer may be interposed between the first electrode AE and the light emitting layer EL. The hole control layer may include a hole transport layer and may further include a hole injection layer. An electron control layer may be disposed between the light emitting layer EL and the second electrode CE. The electron control layer may include an electron transport layer and may further include an electron injection layer. The hole control layer and the electron control layer may be formed, in common, in a plurality of pixels PX by using an open mask.

The encapsulating layer TFE may be disposed on the element layer DP_ED. The encapsulating layer TFE may include a first encapsulating inorganic layer 141, an encapsulating organic layer 142, and a second encapsulating inorganic layer 143, which are sequentially stacked, but layers constituting the encapsulating layer TFE are not limited thereto.

The first and second encapsulating inorganic layers 141 and 143 may protect the element layer DP_ED from moisture and oxygen, and the encapsulating organic layer 142 may protect the element layer DP_ED from foreign substances such as dust particles. The first and second encapsulating inorganic layers 141 and 143 may include a silicon nitride layer, a silicon oxynitride layer, a silicon oxide layer, a titanium oxide layer, or an aluminum oxide layer. The encapsulating organic layer 142 may include, but is not limited to, an acrylic organic layer.

The input sensing layer ISL may be disposed on the display panel DP. The input sensing layer ISL may also be referred to as an input sensor or an input sensing panel. The input sensing layer ISL may include an insulating base layer 210, a first conductive layer 220, a sensing insulating layer 230, a second conductive layer 240, and a protective layer 245.

The insulating base layer 210 may be directly disposed on the display panel DP. The insulating base layer 210 may be an inorganic layer including at least one of silicon nitride, silicon oxynitride, and silicon oxide. Alternatively, the insulating base layer 210 may be an organic layer including an epoxy resin, an acrylate resin, or an imide-based resin. The insulating base layer 210 may have a single-layer structure or may have a multi-layer structure stacked in the third direction DR3.

Each of the first conductive layer 220 and the second conductive layer 240 may have a single-layer structure or a multi-layer stack structure formed in the third direction DR3.

The conductive layer in the single-layer structure may include a metal layer or a transparent conductive layer. The metal layer may include molybdenum, silver, titanium, copper, aluminum, or the alloy thereof. The transparent conductive layer may include transparent conductive oxide, such as indium tin oxide (ITO), indium zinc oxide (IZO), zinc oxide (ZnO), or indium zinc tin oxide (IZTO). In addition, the transparent conductive layer may include conductive polymer, such as Poly(3,4-ethylenedioxythiophene) (PEDOT), a metal nano-wire, or graphene.

The conductive layer having the multi-layer structure may include metal layers. The metal layers may have, for example, a three-layer structure of titanium/aluminum/titanium. The conductive layer in the multi-layer structure may include at least one metal layer and at least one transparent conductive layer.

The sensing insulating layer 230 (may also be referred to as an intermediate insulating layer herein) may be interposed between the first conductive layer 220 and the second conductive layer 240, and the protective layer 245 may be disposed to cover the second conductive layer 240 and the sensing insulating layer 230. The sensing insulating layer 230 and the protective layer 245 may include an inorganic film. The inorganic film may include at least one of an aluminum oxide, a titanium oxide, a silicon oxide, a silicon nitride, a silicon oxynitride, a zirconium oxide, or a hafnium oxide. Alternatively, the sensing insulating layer 230 and the protective layer 245 may include an organic film. The organic film may include at least one of acrylate-based resin, methacrylate-based resin, polyisoprene, vinyl-based resin, epoxy-based resin, urethane-based resin, cellulose-based resin, siloxane-based resin, polyimide-based resin, polyamide-based resin, or perylene-based resin.

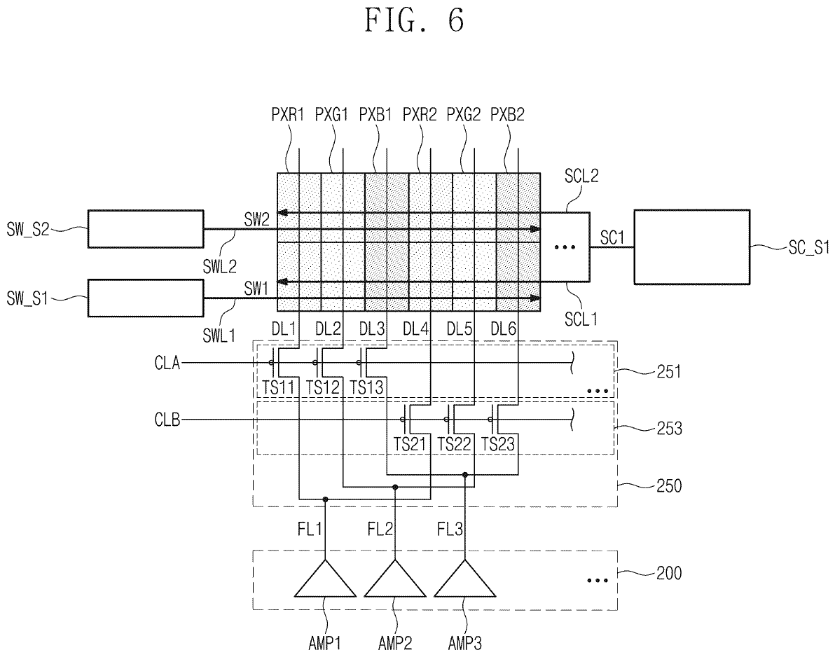

FIG. 6 is a block diagram illustrating the connection between a data driver, a selecting circuit, and data lines according to embodiments of the present disclosure. FIG. 7 is a waveform illustrating first and second selecting signals, first and second write scan signals, and a first compensating scan signal according to embodiments of the present disclosure.

Referring to FIG. 6, the data driver 200 may be connected to the selecting circuit 250 through the fan-out lines FL1, FL2, and FL3. The data driver 200 may include a plurality of output buffers AMP1, AMP2, and AMP3 connected to the fan-out lines FL1, FL2, and FL3, respectively. The output buffers AMP1, AMP2, and AMP3 may output data signals to the fan-out lines FL1, FL2, and FL3. According to embodiments of the present disclosure, the number of the fan-out lines FL1, FL2, and FL3 may be ½ of the number of data lines DL1, DL2, DL3, DL4, DL5, and DL6.

The selecting circuit 250 may include a plurality of switching circuits. According to embodiments of the present disclosure, the selecting circuit 250 includes a first switching circuit 251 and a second switching circuit 253. The first switching circuit 251 and the second switching circuit 253 may be activated alternately. A period, in which the first switching circuit 251 is activated, is referred to as a first selecting period SP1 (see FIG. 7), and a period, in which the second switching circuit 253 is activated, is referred to as a second selecting period SP2 (see FIG. 7). As the first switching circuit 251 is activated during the first selecting period SP1, the fan-out lines FL1, FL2, and FL3 are electrically connected to some (for example, a first data line group) of the data lines DL1 to DL6. As the second switching circuit 253 is activated during the second selecting period SP2, the fan-out lines FL1, FL2, and FL3 are electrically connected to other data lines (for example, a second data line group) of the data lines DL1 to DL6.

The first switching circuit 251 includes a plurality of first switching transistors TS11 to TS13, and the second switching circuit 253 includes a plurality of second switching transistors TS21 to TS23. The plurality of first switching transistors TS11 to TS13 are connected between the first data line group (that is, the first to third data lines DL1 to DL3) and the fan-out lines FL1, FL2, and FL3. The plurality of second switching transistors TS21 to TS23 are connected between the second data line group (that is, the fourth to sixth data lines DL4 to DL6), and the fan-out lines FL1, FL2, and FL3.

A (1-1)-th switching transistor TS11 among the plurality of first switching transistors TS11 to TS13 includes an input electrode connected to the first pan-out line FL1, an output electrode connected to the first data line DL1, and a control electrode to receive a first selecting signal CLA. A (1-2)-th switching transistor TS12 among the plurality of first switching transistors TS11 to TS13 includes an input electrode connected to the second pan-out line FL2, an output electrode connected to the second data line DL2, and a control electrode to receive the first selecting signal CLA. A (1-3)-th switching transistor TS13 among the plurality of first switching transistors TS11 to TS13 includes an input electrode connected to the third pan-out line FL3, an output electrode connected to the third data line DL3, and a control electrode to receive the first selecting signal CLA.

According to embodiments of the present disclosure, the first data line DL1 may be connected to (1-1)-th color pixels PXR1, the second data line DL2 may be connected to (2-1)-th color pixels PXG1, and the third data line DL3 may be connected to (3-1)-th color pixels PXB1. The (1-1)-th, (2-1)-th, and (3-1)-th color pixels PXR1, PXG1, and PXB1 may output mutually different color lights.

A (2-1)-th switching transistor TS21 among the plurality of second switching transistors TS21 to TS23 includes an input electrode connected to the first pan-out line FL1, an output electrode connected to the fourth data line DL4, and a control electrode to receive a second selecting signal CLB. A (2-2)-th switching transistor TS22 among the plurality of second switching transistors TS21 to TS23 includes an input electrode connected to the second pan-out line FL2, an output electrode connected to the fifth data line DL5, and a control electrode to receive the second selecting signal CLB. A (2-3)-th switching transistor TS23 among the plurality of second switching transistors TS21 to TS23 includes an input electrode connected to the third pan-out line FL3, an output electrode connected to the sixth data line DL6, and a control electrode to receive the second selecting signal CLB.

According to embodiments of the present disclosure, the fourth data line DL4 may be connected to (1-2)-th color pixels PXR2, the fifth data line DL5 may be connected to (2-2)-th color pixels PXG2, and the sixth data line DL6 may be connected to (3-2)-th color pixels PXB2. The (1-2)-th, (2-2)-th, and (3-2)-th color pixels PXR2, PXG2, and PXB2 may output mutually different color lights. The (1-1)-th and (1-2)-th color pixels PXR1 and PXR2 may output a first color light (for example, a red light), the (2-1)-th and (2-2)-th color pixels PXG1 and PXG2 may output a second color light (for example, a green light), and the (3-1)-th and (3-2)-th color pixels PXB1 and PXB2 may output a third color light (for example, a blue light).

According to embodiments of the present disclosure, each of the first and second switching transistors TS11 to TS13, and TS21 to TS23 may include a P-type transistor. However, the present disclosure is not limited thereto. Each of the first and second switching transistors TS11 to TS13, and TS21 to TS23 may include an N-type transistor. When each of the first and second switching transistors TS11 to TS13, and TS21 to TS23 may include the P-type transistor, the first and second selecting signals CLA and CLB may have a low level during the first and second selecting periods SP1 and SP2. To the contrary, when each of the first and second switching transistors TS11 to TS13, and TS21 to TS23 may include the N-type transistor, the first and second selecting signals CLA and CLB may have a high level during the first and second selecting periods SP1 and SP2.

The scan driver 300 (see FIG. 3) may include a first scan driver connected to the write scan lines SWL1 to SWLn (see FIG. 3) and a second scan driver connected to the compensating scan lines SCL1 to SCLn (see FIG. 3). The first scan driver may include a plurality of write stages, and the second scan driver may include a plurality of compensating stages. First and second write stages SW_S1 and SW_S2 among the plurality of write scan stages may be connected to first and second write scan lines SWL1 and SWL2 among the write scan lines SWL1 to SWLn, respectively. The first and second write stages SW_S1 and SW_S2 may apply first and second write scan signals SW1 and SW2 to the first and second write scan lines SWL1 and SWL2, respectively. A first compensating stage SC_S1 among the plurality of compensating stages may be connected to first and second compensating scan lines SCL1 and SCL2 among the compensating scan lines SCL1 to SCLn. The first compensating stage SC_S1 may commonly apply a first compensating scan signal SCL1 to the first and second compensating scan lines SCL1 and SLC2. The first compensating signal SC1 may be referred to as a common compensating scan signal which is commonly applied to the first and second compensating scan lines SCL1 and SLC2.

In this case, the (1-1)-th color pixel PXR1 connected to the first data line DL1 and the first write scan line SWL1 is referred to as a first pixel, and the (1-2)-th color pixel PXR2 connected to the fourth data line DL4 and the first write scan line SWL1 is referred to as a second pixel. The (1-1)-th color pixel PXR1 connected to the first data line DL1 and the second write scan line SWL2 is referred to as a third pixel, and the (1-2)-th color pixel PXR2 connected to the fourth data line DL4 and the second write scan line SWL2 is referred to as a fourth pixel. The first pixel and the second pixel are spaced apart from each other in the first direction DR1 (see FIG. 3), and the third pixel and the fourth pixel are spaced apart from each other in the first direction DR1. The first pixel and the third pixel are adjacent to each other in the second direction DR2 (see FIG. 3), and the second pixel and the fourth pixel are adjacent to each other in the second direction DR2.

Referring to FIGS. 6 and 7, a first pixel row connected to the first write scan line SWL1 and the first compensating scan line SCL1 may be turned on during a first horizontal scan period H1, and a second pixel row connected to the second write scan line SWL2 and the second compensating scan line SCL2 may be turned on during a second horizontal scan period H2. Each of the first and second horizontal scan periods H1 and H2 may include the first selection period SP1 and the second selection period SP2. When the first selecting signal CLA is activated during the first selecting period SP1, the first switching transistors TS11 to TS13 may be turned on, and the data signals, which are provided to the fan-out lines FL1, FL2, and FL3, may be applied to the first data line group DL1 to DL3 through the first switching transistors TS11 to TS13. When the second selecting signal CLB is activated during the second selecting period SP2, the second switching transistors TS21 to TS23 may be turned on, and the data signals, which are provided to the fan-out lines FL1, FL2, and FL3, may be applied to the second data line group DL4 to DL6 through the second switching transistors TS21 to TS23.

In particular, a (1-1)-th data signal D11 is applied to the first data line DL1 during the first selecting period SP1 of the first horizontal scan period H1, and a (4-1)-th data signal D41 is applied to the fourth data line DL4 during the second selecting period SP2 of the first horizontal scan period H1. In addition, a (1-2)-th data signal D12 is applied to the first data line DL1 during the first selecting period SP1 of the second horizontal scan period H2, and a (4-2)-th data signal D42 is applied to the fourth data line DL4 during the second selecting period SP2 of the second horizontal scan period H2.

The (1-1)-th data signal D11 and the (4-1)-th data signal D41 applied to the first and fourth data lines DL1 and DL4 during the first horizontal scan period H1 may be written to the (1-1)-th color pixel PXR1 and the (1-2)-th color pixel PXR2 positioned in the first pixel row during a (1-1)-th activation period AP11 of the first write scan signal SW1. The (1-2)-th data signal D12 and the (4-2)-th data signal D42 applied to the first and fourth data lines DL1 and DL4 during the second horizontal scan period H2 may be written to the (1-1)-th color pixel PXR1 and the (1-2)-th color pixel PXR2 positioned in the second pixel row during a (1-2)-th activation period AP12 of the second write scan signal SW2.

Even if data signals having the same grayscale information (or similar grayscale information) are applied to the (1-1)-th color pixel PXR1 and the (1-2)-th color pixel PXR2 positioned in the first pixel row, when the (1-1)-th color pixel PXR1 and the (1-2)-th color pixel PXR2 operate during mutually different selecting periods, the difference in luminance between the (1-1)-th color pixel PXR1 and the (1-2)-th color pixel PXR2 may be made. Similarly, even if data signals having the same grayscale information (or similar grayscale information) are applied to the (1-1)-th color pixel PXR1 and the (1-2)-th color pixel PXR2 positioned in the second pixel row, when the (1-1)-th color pixel PXR1 and the (1-2)-th color pixel PXR2 operate during mutually different selecting periods, the difference in luminance between the (1-1)-th color pixel PXR1 and the (1-2)-th color pixel PXR2 may be made.

The second activation period AP2 of the first compensating scan signal SC1 may be overlapped with the first horizontal scan period H1 and the second horizontal scan period H2. In particular, the second activation period AP2 of the first compensating scan signal SC1 may be overlapped with the (1-1)-th activation period AP11 of the first write scan signal SW1 and the (1-2)-th activation period AP12 of the second write scan signal SW2. The compensating period of the (1-1)-th color pixel PXR1 and the (1-2)-th color pixel PXR2 positioned in the second pixel row may have a longer duration than the compensating period of the (1-1)-th color pixel PXR1 and the (1-2)-th color pixel PXR2 positioned in the first pixel row. When the compensating periods have mutually different durations, the difference in luminance between the first pixel row and the second pixel row may be made.

To compensate for the difference in luminance between the pixels, the driving controller 100 (see FIG. 3) according to the present disclosure may include a compensating circuit.

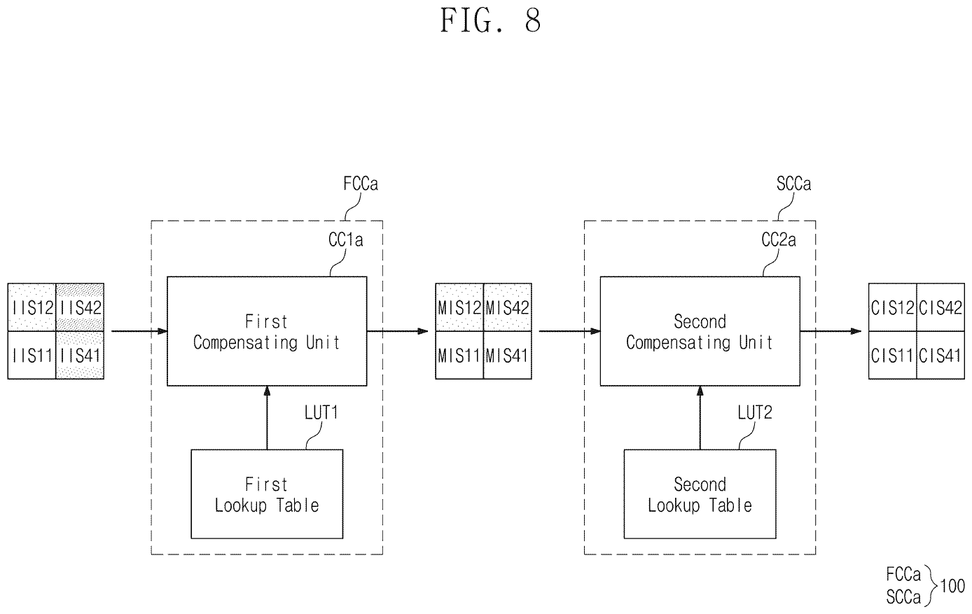

FIG. 8 is a block diagram of a driving controller according to embodiments of the present disclosure.

Referring to FIG. 8, the driving controller 100 includes a first compensating circuit FCCa and a second compensating circuit SCCa. The first compensating circuit FCCa may be configured to compensate for the difference in luminance between the first pixel and the second pixel, and the difference in luminance between the third pixel and the fourth pixel. The second compensating circuit SCCa may be configured to compensate for the difference in luminance between the first pixel and the third pixel, and the difference in luminance between the second pixel and the fourth pixel.

The first compensating circuit FCCa includes a first compensating unit CC1a to receive first to fourth input image signals IIS11, IIS41, IIS12, and IIS42 corresponding to the first to fourth pixels. The first compensating unit CC1a compensates for the first to fourth input image signals IIS11, IIS41, IIS12, and IIS42 using a first compensating value and a second compensating value to obtain first to fourth intermediate image signals MIS11, MIS41, MIS12, and MIS42. The first compensating value is based on the difference in luminance between the first pixel and the second pixel, and the second compensating value is based on the difference in luminance between the third pixel and the fourth pixel. The first compensating circuit FCCa may further include a first lookup table LUT1 to store the first compensating value and the second compensating value.

When the first and second pixels receive the (1-1)-th and (4-1)-th data signals D11 and D41 (see FIG. 7) corresponding to the first and second intermediate image signals MIS11 and MIS41, the difference in luminance between the first and second pixels may be compensated. Also, when the third and fourth pixels receive the (1-2)-th and (4-2)-th data signals D12 and D42 (see FIG. 7) corresponding to the third and fourth intermediate image signals MIS12 and MIS42, the difference in luminance between the third and fourth pixels may be compensated.

The second compensating circuit SCCa includes a second compensating unit CC2a to receive the first to fourth input image signals MIS11, MIS41, MIS12, and MIS42 from the first compensating circuit FCCa. The second compensating unit CC2a compensates for the first to fourth intermediate image signals MIS11, MIS41, MIS12, and MIS42 to obtain first to fourth compensated image signals CIS11, CIS41, CIS12, and CIS42 using a third compensating value and a fourth compensating value. The third compensating value is based on the difference in luminance between the first pixel and the third pixel, and the fourth compensating value is based on the difference in luminance between the second pixel and the fourth pixel. The second compensating circuit SCCa may further include a second lookup table LUT2 to store a third compensating value and a fourth compensating value.

When the first and fourth pixels receive the (1-1)-th and (4-2)-th data signals D11, D41, D12, and D42 (see FIG. 7) corresponding to the first to fourth compensated image signals CIS11, CIS41, CIS12, and CIS42, the difference in luminance between the first and third pixels and the difference in luminance between the second pixel and the fourth pixel may be compensated.

As described above, as the driving controller 100 includes two compensating circuits FCCa and SCCa, the difference in luminance between the pixels in the first direction DR1 and the difference in luminance between the pixels in the second direction DR2 may be compensated, thereby preventing the image quality from being degraded due to the difference in luminance between the pixels (or reducing the degradation).

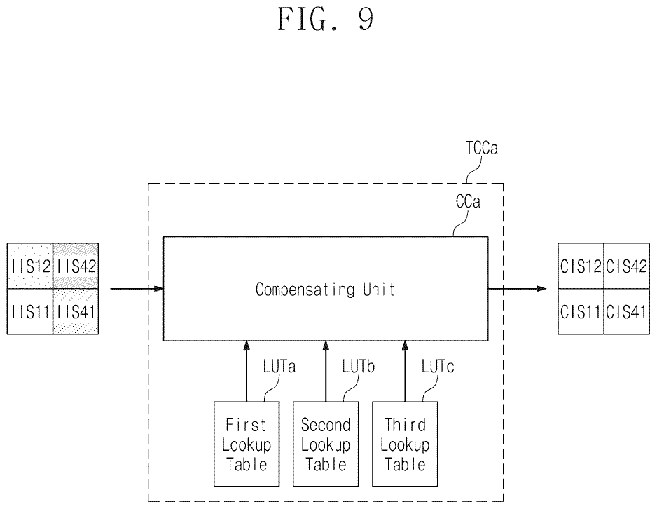

FIG. 9 is a block diagram of a driving controller according to embodiments of the present disclosure.

Referring to FIG. 9, the driving controller 100 (see FIG. 3) includes an integrated compensating circuit TCCa. The integrated compensating circuit TCCa may be configured to generate compensated image signals using the differences in luminance between one reference pixel (e.g., only one reference pixel) selected from among the first to fourth pixels and remaining pixels from among the first to fourth pixels. According to embodiments of the present disclosure, the first pixel may be selected as the reference pixel, and the remaining pixels may be the second to fourth pixels. The integrated compensating circuit TCCa may be configured to compensate for the differences in luminance between the first pixel, and the second to fourth pixels.

The integrated compensating circuit TCCa includes a compensating unit CCa to receive the first to fourth input image signals IIS11, IIS41, IIS12, and IIS42 corresponding to the first to fourth pixels. The compensating unit CCa may compensate for the first to fourth input image signals IIS11, IIS41, IIS12, and IIS42 to obtain the first to fourth compensated image signals CIS11, CIS41, CIS12, and CIS42 using a first compensating value, a second compensating value, and a third compensating value. The first compensating value is based on the difference in luminance between the first pixel and the second pixel, and the second compensating value is based on the difference in luminance between the first pixel and the third pixel, and the third compensating value is based on the difference in luminance between the first and fourth pixels. When the first pixel is the reference pixel, the first compensated image signal CIS11 may be a signal the same as (or similar to) the first input image signal IIS11.

The integrated compensating circuit TCCa may include a first lookup table LUTa to store the first compensating value, a second lookup table LUTb to store the second compensating value, and a third lookup table LUTc to store the third compensating value.

When the first and fourth pixels receive the (1-1)-th and (4-2)-th data signals D11, D41, D12, and D42 (see FIG. 7) corresponding to the first to fourth compensated image signals CIS11, CIS41, CIS12, and CIS42, the differences in luminance between the first pixel (that is, the reference pixel), and the second to fourth pixels (that is, the remaining pixels) may be compensated. Accordingly, the image quality may be prevented from being degraded due to the difference in luminance between the pixels (or the degradation may be reduced). Accordingly, the whole display quality of the display device DD (see FIG. 3) may be improved.

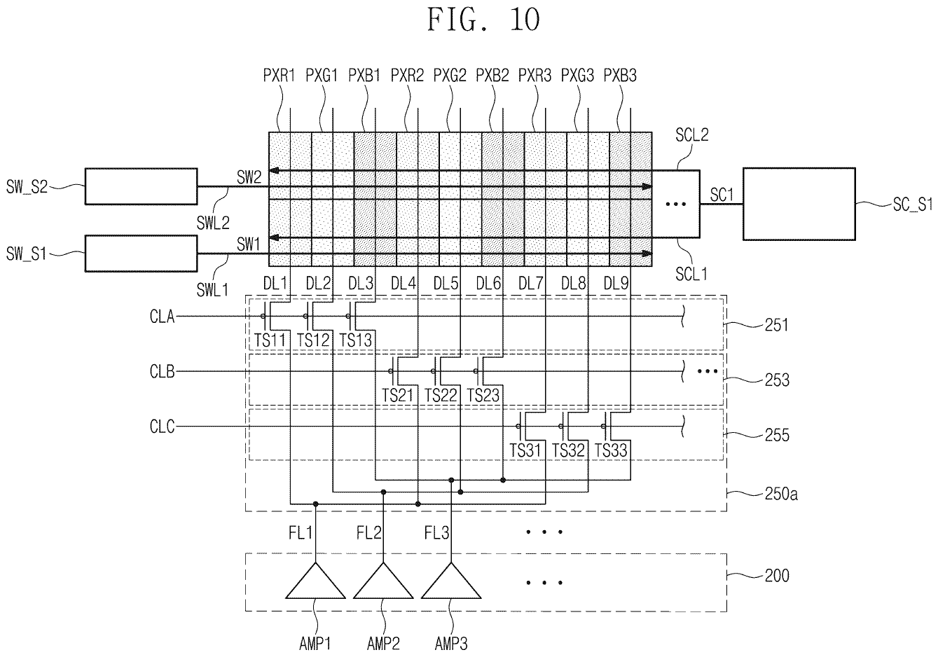

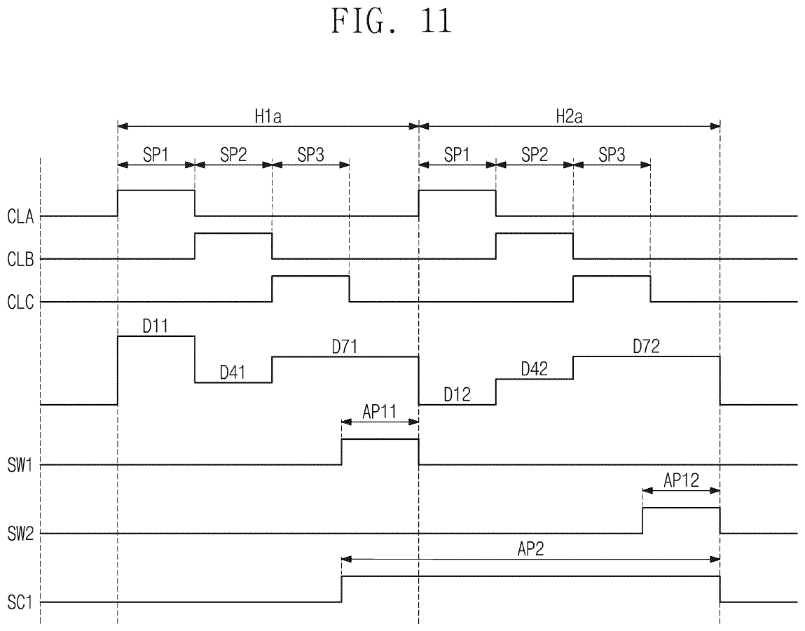

FIG. 10 is a block diagram illustrating the connection between a data driver, a selecting circuit, and data lines according to embodiments of the present disclosure. FIG. 11 is a waveform illustrating first to third selecting signals, first and second write scan signals, and a first compensating scan signal according to embodiments of the present disclosure.

Components, which are the same as (or similar to) the components illustrated in FIGS. 6 and 7, from among components illustrated in FIGS. 10 and 11 will be assigned with the same reference numerals (or similar reference numerals), and thus, additional description will be omitted to avoid redundancy.

Referring to FIGS. 10 and 11, the data driver 200 may be connected to a selecting circuit 250a through the fan-out lines FL1, FL2, and FL3. The data driver 200 may include the plurality of output buffers AMP1, AMP2, and AMP3 connected to the fan-out lines FL1, FL2, and FL3, respectively. The output buffers AMP1, AMP2, and AMP3 may output data signals to the fan-out lines FL1, FL2, and FL3. According to embodiments of the present disclosure, the number of the fan-out lines FL1, FL2, and FL3 may be ⅓ of the number of data lines DL1, DL2, DL3, DL4, DL5, DL6, DL7, DL8, and DL9.

The selecting circuit 250a may include a plurality of switching circuits. According to embodiments of the present disclosure, the selecting circuit 250a includes the first switching circuit 251, the second switching circuit 253, and a third switching circuit 255. The first to third switching circuits 251, 253, and 255 may be activated alternately. A period, in which the first switching circuit 251 is activated, is referred to as a first selecting period SP1 (see FIG. 11), a period, in which the second switching circuit 253 is activated, is referred to as a second selecting period SP2 (see FIG. 11), and a period, in which the third switching circuit 255 is activated, is referred to as a third selecting period SP3 (see FIG. 11). As the first switching circuit 251 is activated during the first selecting period SP1, the fan-out lines FL1, FL2, and FL3 are electrically connected to some (for example, a first data line group) of the data lines DL1 to DL9. As the second switching circuit 253 is activated during the second selecting period SP2, the fan-out lines FL1, FL2, and FL3 are electrically connected to some (for example, a second data line group) of the data lines DL1 to DL9. As the third switching circuit 255 is activated during the third selecting period SP3, the fan-out lines FL1, FL2, and FL3 are electrically connected to some (for example, a third data line group) of the data lines DL1 to DL9.

The first switching circuit 251 includes a plurality of first switching transistors TS11 to TS13, and the second switching circuit 253 includes a plurality of second switching transistors TS21 to TS23. The third switching circuit 255 includes a plurality of third switching transistors TS31 to TS33. The plurality of first switching transistors TS11 to TS13 are connected between the first data line group (that is, the first to third data lines DL1 to DL3) and the fan-out lines FL1, FL2, and FL3. The plurality of second switching transistors TS21 to TS23 are connected between the second data line group (that is, the fourth to sixth data lines DL4 to DL6), and the fan-out lines FL1, FL2, and FL3. The plurality of third switching transistors TS31 to TS33 are connected between the third data line group (that is, the seventh to ninth data line DL7 to DL9) and the fan-out lines FL1, FL2, and FL3.

A (3-1)-th switching transistor TS31 among the plurality of third switching transistors TS31 to TS33 includes an input electrode connected to the first pan-out line FL1, an output electrode connected to the seventh data line DL7, and a control electrode to receive a third selecting signal CLC. A (3-2)-th switching transistor TS32 among the plurality of third switching transistors TS31 to TS33 includes an input electrode connected to the second pan-out line FL2, an output electrode connected to the eighth data line DL8, and a control electrode to receive the third selecting signal CLC. A (3-3)-th switching transistor TS33 among the plurality of third switching transistors TS31 to TS33 includes an input electrode connected to the third pan-out line FL3, an output electrode connected to the ninth data line DL9, and a control electrode to receive the third selecting signal CLC.

According to embodiments of the present disclosure, the seventh data line DL7 may be connected to (1-3)-th color pixels PXR3, the eighth data line DL8 may be connected to (2-3)-th color pixels PXG3, and the ninth data line DL9 may be connected to (3-3)-th color pixels PXB3. The (1-3)-th, (2-3)-th, and (3-3)-th color pixels PXR3, PXG3, and PXB3 may output mutually different color lights. The (1-1)-th, (1-2)-th, and (1-3)-th color pixels PXR1, PXR2, and PXR3 may output a first color light (for example, a red light), the (2-1)-th, (2-2)-th, and (2-3)-th color pixels PXG1, PXG2, and PXG3 may output a second color light (for example, a green light), and the (3-1)-th, (3-2)-th, and (3-3)-th color pixels PXB1, PXB2, and PXB2 may output a third color light (for example, a blue light).

In this case, the (1-1)-th color pixel PXR1 connected to the first data line DL1 and the first write scan line SWL1 is referred to as a first pixel, and the (1-2)-th color pixel PXR2 connected to the fourth data line DL4 and the first write scan line SWL1 is referred to as a second pixel. The (1-1)-th color pixel PXR1 connected to the first data line DL1 and the second write scan line SWL2 is referred to as a third pixel, and the (1-2)-th color pixel PXR2 connected to the fourth data line DL4 and the second write scan line SWL2 is referred to as a fourth pixel. The (1-3)-th color pixel PXR3 connected to the seventh data line DL7 and the first write scan line SWL1 is referred to as a fifth pixel, and the (1-3)-th color pixel PXR3 connected to the seventh data line DL7 and the second write scan line SWL2 is referred to as a sixth pixel.

The first, second, and fifth pixels are spaced apart from each other in the first direction DR1 (see FIG. 3), and the third, fourth, and sixth pixels are spaced apart from each other in the first direction DR1. The first pixel and the third pixel are adjacent to each other in the second direction DR2 (see FIG. 3), the second pixel and the fourth pixel are adjacent to each other in the second direction DR2, and the fifth pixel and the sixth pixel are adjacent to each other in the second direction DR2.

When the third selecting signal CLC is activated during the third selecting period SP3, the second switching transistors TS31 to TS33 may be turned on, and the data signals, which are provided to the fan-out lines FL1, FL2, and FL3, may be applied to the second data line group DL7 to DL9 through the third switching transistors TS31 to TS33.

In particular, the (1-1)-th data signal D11 is applied to the first data line DL1 during the first selecting period SP1 of the first horizontal scan period H1a, the (4-1)-th data signal D41 is applied to the fourth data line DL4 during the second selecting period SP2 of the first horizontal scan period H1a, and the (7-1)-th data signal D71 is applied to the seventh data line DL7 during the third selecting period SP3 of the first horizontal scan period H1a, In addition, the (1-2)-th data signal D12 is applied to the first data line DL1 during the first selecting period SP1 of the second horizontal scan period H2a, the (4-2)-th data signal D42 is applied to the fourth data line DL4 during the second selecting period SP2 of the second horizontal scan period H2a, and the (7-2)-th data signal D72 is applied to the seventh data line DL7 during the third selecting period SP3 of the second horizontal scan period H2a.

The (1-1)-th data signal D11, the (4-1)-th data signal D41, the (7-1)-th data signal D71 applied to the first, fourth, and seventh data lines DL1, DL4, and DL7 during the first horizontal scan period H1a may be written to the (1-1)-th color pixel PXR1, the (1-2)-th color pixel PXR2, and the (1-3)-th color pixel PXR3 positioned in the first pixel row during a (1-1)-th activation period AP11 of the first write scan signal SW1. The (1-2)-th data signal D12, the (4-2)-th data signal D42, and the (7-2)-th data signal D72 applied to the first, fourth, and seventh data lines DL1, DL4, and DL7 during the second horizontal scan period H2a may be written to the (1-1)-th color pixel PXR1, the (1-2)-th color pixel PXR2, and the (1-3)-th color pixel PXR3 positioned in the second pixel row during a (1-2)-th activation period AP12 of the second write scan signal SW2.

Even if data signals having the same grayscale information (or similar grayscale information) are applied to the (1-1)-th color pixel PXR1, the (1-2)-th color pixel PXR2, and the (1-3)-th color pixel PXR3 positioned in the first pixel row, when the (1-1)-th color pixel PXR1, the (1-2)-th color pixel PXR2, and the (1-3)-th color pixel PXR3 operate during mutually different selecting periods, the difference in luminance among the (1-1)-th color pixel PXR1, the (1-2)-th color pixel PRX2, and the (1-3)-th color pixel PXR3 may be made. Similarly, even if data signals having the same grayscale information (or similar grayscale information) are applied to the (1-1)-th color pixel PXR1, the (1-2)-th color pixel PXR2, and the (1-3)-th color pixel PXR3 positioned in the second pixel row, when the (1-1)-th color pixel PXR1, the (1-2)-th color pixel PXR2, and the (1-3)-th color pixel PXR3 operate during mutually different selecting periods, the difference in luminance among the (1-1)-th color pixel PXR1, the (1-2)-th color pixel PRX2, and the (1-3)-th color pixel PXR3 may be made.

The second activation period AP2 of the first compensating scan signal SC1 may be overlapped with the (1-1)-th activation period AP11 of the first write scan signal SW1 and the (1-2)-th activation period AP12 of the second write scan signal SW2. The compensating period of the (1-1)-th color pixel PXR1, the (1-2)-th color pixel PXR2, and the (1-3)-th color pixel PXR3 positioned in the second pixel row may have a longer duration than the compensating period of the (1-1)-th color pixel PXR1, the (1-2)-th color pixel PXR2, and the (1-3)-th color pixel PXR3 positioned in the first pixel row. When the compensating periods have mutually different durations, the differences in luminance between the first pixel row and the second pixel row may be caused.

To compensate for the difference in luminance between the pixels, the driving controller 100 (see FIG. 3) according to the present disclosure may include a compensating circuit.

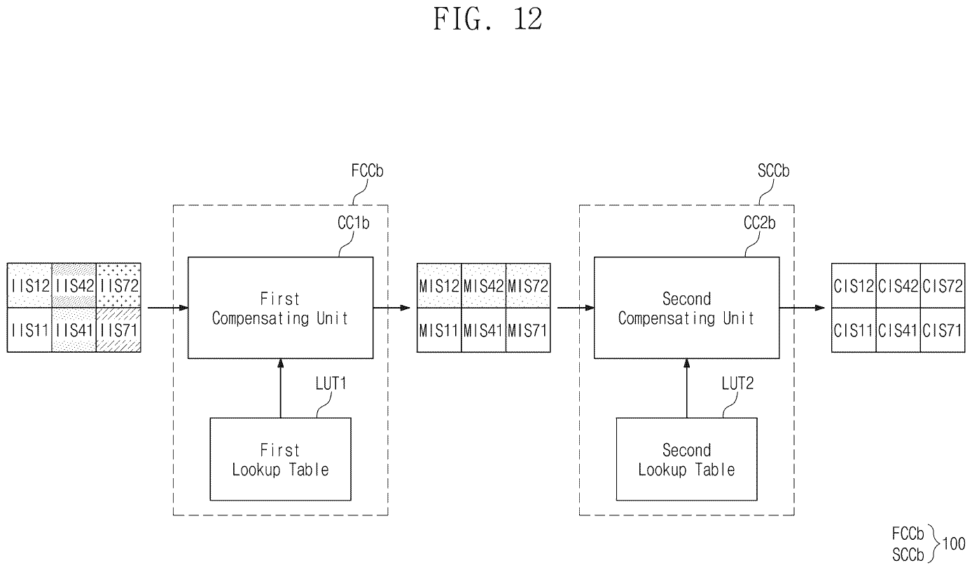

FIG. 12 is a block diagram of a driving controller according to embodiments of the present disclosure.

Referring to FIG. 12, the driving controller 100 includes a first compensating circuit FCCb and a second compensating circuit SCCb. The first compensating circuit FCCb may be configured to compensate for the difference in luminance among the first pixel, the second pixel, and the fifth pixel, and the difference in luminance among the third pixel, the fourth pixel, and the sixth pixel. The second compensating circuit SCCb may be configured to compensate for the difference in luminance between the first pixel and the third pixel, the difference in luminance between the second pixel and the fourth pixel, and the difference in luminance between the fifth and sixth pixels.

The first compensating circuit FCCb includes a first compensating unit CC1b to receive first to sixth input image signals IIS11, IIS41, IIS12, IIS42, IIS71, and IIS72 corresponding to the first to sixth pixels. The first compensating unit CC1b may compensate for the first to sixth input image signals IIS11, IIS41, IIS12, IIS42, IIS71, and IIS72 to obtain the first to sixth intermediate image signals MIS11, MIS41, MIS12, MIS42, MIS71, and MIS72 using a first compensating value, a second compensating value, a fifth compensating value, and a sixth compensating value. The first compensating value is based on the difference in luminance between the first pixel and the second pixel, the second compensating value is based on the difference in luminance between the third and fourth pixels, the fifth compensating value is based on the difference in luminance between the first pixel and the fifth pixel, and the sixth compensating value is based on the difference in luminance between the third pixel and the sixth pixel. The first compensating circuit FCCb may further include a first lookup table LUT1 to store the first and second compensating values, and the fifth and sixth compensating values.

When the first and fifth pixels receive the (1-1)-th, (4-1)-th, and (7-1)-th data signals D11, D41, and D71 (see FIG. 7) corresponding to the first, second, and fifth intermediate image signals MIS11, MIS41, and MIS71, the difference in luminance among the first, second, and fifth pixels may be compensated. Also, when the third, fourth, and sixth pixels receive the (1-2)-th, (4-2)-th, and (7-2)-th data signals D12, D42, and D72 (see FIG. 7) corresponding to the third, fourth, and sixth intermediate image signals MIS12, MIS42, and MIS72, the difference in luminance among the third, fourth, and sixth pixels may be compensated.

The second compensating circuit SCCb includes a second compensating unit CC2b to receive the first to sixth input image signals MIS11, MIS41, MIS12, MIS42, MIS71, and MIS72 from the first compensating circuit FCCb. The second compensating unit CC2b may compensate for the first to sixth intermediate image signals MIS11, MIS41, MIS12, MIS42, MIS71, and MIS72 to obtain the first to sixth compensated image signals CIS11, CIS41, CIS12, CIS42, CIS71, and CIS72 using a third compensating value, a fourth compensating value, and a seventh compensating value. The third compensating value is based on the difference in luminance between the first pixel and the third pixel, the fourth compensating value is based on the difference in luminance between the second pixel and the fourth pixel, and the seventh compensating value is based on the difference in luminance between the fifth and sixth pixels. The second compensating circuit SCCb may further include a second lookup table LUT2 to store the third compensating value, the fourth compensating value, and the seventh compensating value.

When the first and sixth pixels receive the (1-1)-th to (7-2)-th data signals D11, D41, D12, D42, D71, and D72 (see FIG. 7) corresponding to the first to sixth compensated image signal CIS11, CIS41, CIS12, CIS42, CIS71, and CIS72, the difference in luminance between the first and third pixels, the difference in luminance between the second pixel and the fourth pixel, and the difference in luminance between the fifth pixel and the sixth pixel may be compensated.

As described above, the driving controller 100 includes two compensating circuits FCCb and SCCb, the difference in luminance between the pixels in the first direction DR1, and the difference in luminance between the pixels in the second direction DR2 may be compensated, thereby preventing the image quality from being degraded due to the difference in luminance between the pixels (or reducing the amount of degradation).

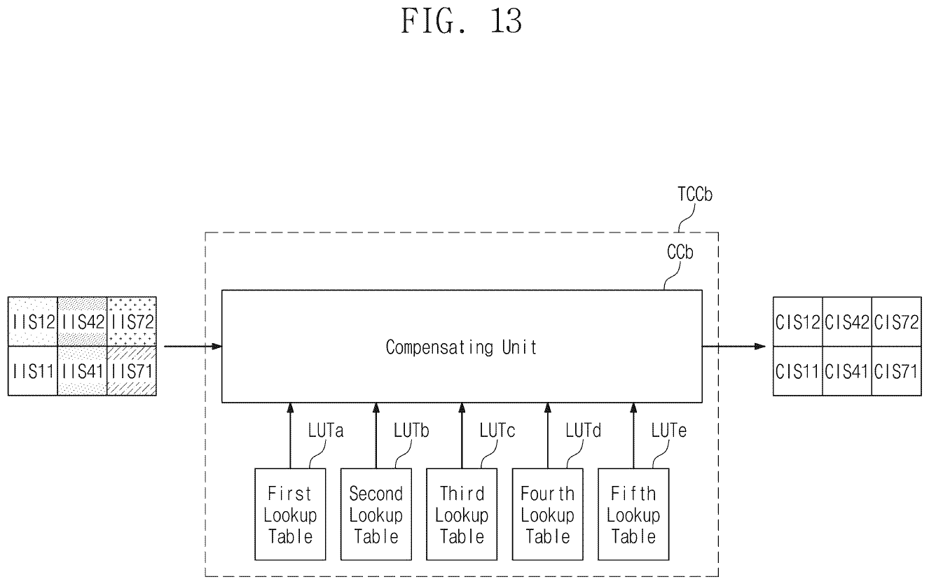

FIG. 13 is a block diagram of a driving controller according to embodiments of the present disclosure.

Referring to FIG. 13, the driving controller 100 (see FIG. 3) includes an integrated compensating circuit TCCb. The integrated compensating circuit TCCb may be configured to generate compensated image signals using the difference in luminance between one reference pixel (e.g., only one reference pixel) selected from among the first to sixth pixels and remaining pixels from among the first to sixth pixels. According to embodiments of the present disclosure, the first pixel may be selected as the reference pixel, and the remaining pixels may be the second to sixth pixels. The integrated compensating circuit TCCb may be configured to compensate for the differences in luminance between the first pixel, and the second to sixth pixels.

The integrated compensating circuit TCCb includes a compensating unit CCb to receive the first to sixth input image signals IIS11, IIS41, IIS12, IIS42, IIS71, and IIS72 corresponding to the first to sixth pixels. The compensating unit CCb may compensate for the first to sixth input image signals IIS11, IIS41, IIS12, IIS42, IIS71, and IIS72 to obtain the first to sixth compensated image signals CIS11, CIS41, CIS12, CIS42, CIS71, and CIS72 using a first compensating value, a second compensating value, a third compensating value, a fourth compensating value, and a fifth compensating value. The first compensating value is based on the difference in luminance between the first and second pixel, the second compensating value is based on the difference in luminance between the first and third pixels, the third compensating value is based on the difference in luminance between the first and fourth pixels, the fourth compensating value is based on the difference in luminance between the first and fifth pixels, and the fifth compensating value is based on the difference in luminance between the first and sixth pixels. In this case, when the first pixel is the reference pixel, the first compensated image signal CIS1 may be a signal the same as (or similar to) the first input image signal IIS1.

The integrated compensating circuit TCCb may further include a first lookup table LUTa to store the first compensating value, a second lookup table LUTb to store the second compensating value, a third lookup table LUTc to store the third compensating value, a fourth lookup table LUTd to store the fourth compensating value, and a fifth lookup table LUTe to store the fifth compensating value.

When the first and sixth pixels receive the (1-1)-th to (7-2)-th data signals D11, D41, D12, D42, D71, and D72 (see FIG. 7) corresponding to the first to sixth compensated image signal CIS11, CIS41, CIS12, CIS42, CIS71, and CIS72, the difference in luminance between the first pixel (that is, the reference pixel), and the second to sixth pixels (that is, the remaining pixels) may be compensated. Accordingly, the image quality may be prevented from being degraded due to the difference in luminance between the pixels (or the amount of degradation may be reduced). Accordingly, the whole display quality of the display device DD (see FIG. 3) may be improved.

The display module according to embodiments may be applied to various electronic apparatuses. According to embodiments, the electronic apparatus may include a display module described above, and may further include a module or a device having an additional function in addition to the display device.

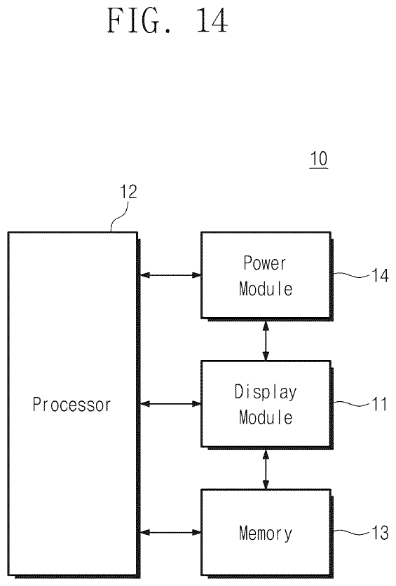

FIG. 14 is a block diagram illustrating a driving controller according to embodiments of the present disclosure.

Referring to FIG. 14, the electronic apparatus 10 according to embodiments may include a display module 11, a processor 12, a memory 13, and/or a power module 14.

The processor 12, which controls the driving of the display module 11, may include a central processing unit (CPU), an application processor (AP), a graphic processing unit (GPU), a communication processor (CP), an image signal processor (ISP), or a controller.

The memory 13 may store data information necessary (or otherwise, used) for the operation of the processor 12 or the display module 11. When the processor 12 runs the application stored in the memory 13, an image data signal and/or an input control signal may be transmitted to the display module 11, and the display module 11 may process the transmitted signal and output the image information through the display screen.

The power module 14 may include a power supply module, such as a power adaptor or a battery device, and a power converting module to convert the power supplied from the power supply module into power necessary (or otherwise, used) for the operation of the electronic apparatus 10.

At least one of components of the above-described electronic apparatus 10 may be included in the display module according to embodiments described above. In addition, some of individual modules functionally included in one module may be included in the display module, and others of the individual modules may be provided separately from the display module. For example, the display module 11 may be included in the display device, and the processor 12, the memory 13, and the power module 14 may be provided in the form of another device in the electronic apparatus 10 instead of the display device.

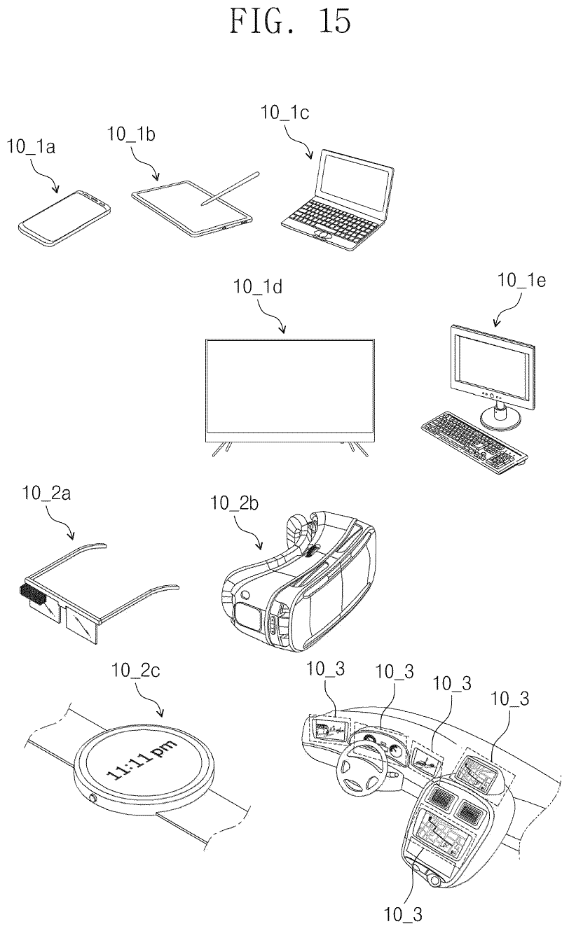

FIG. 15 illustrates schematic views of an electronic apparatus according to embodiments.

Referring to FIG. 15, various electronic apparatuses employing the display module according to embodiments may include a wearable electronic apparatus including a display module such as smart glasses 10_2a, a head mounted display 10_2b, a smart watch 10_2c, etc., and an electronic apparatus 10-3 for the vehicle including the display module such as a center information display (CID), which is disposed in an instrument panel, a centerfecia, and/or a dashboard of a vehicle, or a room mirror display, as well as an electronic apparatus for image display such as a smartphone 10_1a, a tablet PC 10_1b, a laptop computer 10_1c, a television (TV) 10_1d, a desk monitor 10_1e, etc.

As described above, the driving controller may include two compensating circuits in the structure having a selecting circuit provided between the data driver and the data lines, thereby compensating for the difference in luminance between the pixels in the first direction and the difference in luminance between the pixels in the second direction. Accordingly, the image quality may be prevented from being degraded due to the difference in luminance between the pixels (or the amount of degradation may be reduced), and the display quality of the display device may be improved as a whole.

Conventional display devices activate a compensating scan signal in a given pixel row for a different compensating period duration than in another pixel row (e.g., an adjacent pixel row). These different compensating period durations result in differences in luminance between the pixel rows. The conventional display devices suffer from degraded image quality due to the differences in luminance.

However, according to embodiments, improved display devices are provided. For example, the improved display devices compensate image signals for the differences in luminance between corresponding pixels rows before providing the image signals to the pixels. Accordingly, the pixels of the pixel rows generate light of uniform (or similar) luminance based on the compensated image signals, thereby preventing or reducing the degradation in image quality suffered by the conventional display devices.

According to embodiments, operations described herein as being performed by the display device DD, the display module DM, the display panel DP, the driving chip DIC, the driving controller 100, the data driver 200, the selecting circuit 250, the scan driver 300, the light emitting driver 350, the voltage generator 400, each of the output buffers AMP1, AMP2 and AMP3, the first switching circuit 251, the second switching circuit 253, each among the plurality of write stages (e.g., the first and second write stages SW_S1 and SW_S2), each among the plurality of compensating stages (e.g., the compensating stage SC_S1), the first compensating circuit FCCa, the second compensating circuit SCCa, the first compensating unit CC1a, the second compensating unit CC2a, the integrated compensating circuit TCCa, the compensating unit CCa, the selecting circuit 250a, the third switching circuit 255, the first compensating circuit FCCb, the second compensating circuit SCCb, the first compensating unit CC1b, the second compensating unit CC2b, the integrated compensating circuit TCCb, the compensating unit CCb, the electronic apparatus 10, the display module 11, the processor 12, and/or the power module 14 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the first lookup table LUT1, the second lookup table LUT2, the first lookup table LUTa, the second lookup table LUTb, the third lookup table LUTc, the fourth lookup table LUTd, the fifth lookup table LUTe and/or the memory 13). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail herein. Although discussed in a particular manner, a function or operation specified in a specific block may be performed differently from the flow specified in a flowchart, flow diagram, etc. For example, functions or operations illustrated as being performed serially in two consecutive blocks may actually be performed concurrently, simultaneously, contemporaneously, or in some cases be performed in reverse order.

Although embodiments of the present disclosure have been described for illustrative purposes, those skilled in the art will appreciate that various modifications, and substitutions are possible, without departing from the scope and spirit of the present disclosure as disclosed in the accompanying claims.

Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a driving controller configured to receive input image signals and compensate the input image signals to obtain compensated image signals;
a selecting circuit including a first switching circuit activated in response to a first selecting signal and a second switching circuit activated in response to a second selecting signal; and
a display panel configured to display an image, the display panel including,
a first pixel connected to a first data line and a first write scan line, the first data line being connected to the first switching circuit,
a second pixel connected to a second data line and the first write scan line, the second data line being connected to the second switching circuit,
a third pixel connected to the first data line and a second write scan line, the second write scan line being adjacent to the first write scan line, and
a fourth pixel connected to the second data line and the second write scan line, wherein the driving controller includes processing circuitry configured to,
compensate for a difference in luminance between the first pixel and the second pixel,
compensate for a difference in luminance between the third pixel and the fourth pixel,
compensate for a difference in luminance between the first pixel and the third pixel, and
compensate for a difference in luminance between the second pixel and the fourth pixel.

2. The display device of claim 1, wherein the processing circuitry is configured to:
receive a first input image signal, a second input image signal, a third input image signal and a fourth input image signal respectively corresponding to the first pixel, the second pixel, the third pixel and the fourth pixel; and
compensate for the first input image signal, the second input image signal, the third input image signal and the fourth input image signal using a first compensating value and a second compensating value to respectively obtain a first intermediate image signal, a second intermediate image signal, a third intermediate image signal and a fourth intermediate image signal, the first compensating value being based on the difference in luminance between the first pixel and the second pixel, and the second compensating value being based on the difference in luminance between the third pixel and the fourth pixel.

3. The display device of claim 2, further comprising:
a first lookup table configured to store the first compensating value and the second compensating value.

4. The display device of claim 2, wherein the processing circuitry is configured to:
compensate for the first intermediate image signal, the second intermediate image signal, the third intermediate image signal and the fourth intermediate image signal using a third compensating value and a fourth compensating value to respectively obtain a first compensated image signal, a second compensated image signal, a third compensated image signal and a fourth compensated image signal, the third compensating value being based on the difference in luminance between the first pixel and the third pixel, and the fourth compensating value being based on the difference in luminance between the second pixel and the fourth pixel.

5. The display device of claim 4, further comprising:
a second lookup table configured to store the third compensating value and the fourth compensating value.

6. The display device of claim 1, wherein
the first write scan line receives a first write scan signal having a (1-1)-th activation period overlapped with a first horizontal scan period;
the second write scan line receives a second write scan signal having a (1-2)-th activation period overlapped with a second horizontal scan period;
the first selecting signal is activated during a first selecting period of each of the first horizontal scan period and the second horizontal scan period; and
the second selecting signal is activated during a second selecting period of each of the first horizontal scan period and the second horizontal scan period.

7. The display device of claim 6, wherein
the first pixel and the second pixel are connected to a first compensating scan line;
the third pixel and the fourth pixel are connected to a second compensating scan line; and
a common compensating scan signal commonly applied to the first compensating scan line and the second compensating scan line includes a second activation period overlapped with the first horizontal scan period and the second horizontal scan period.

8. The display device of claim 1, wherein the first pixel, the second pixel, the third pixel and the fourth pixel express a same color.

9. The display device of claim 1, wherein
the selecting circuit includes a third switching circuit activated in response to a third selecting signal; and
the display panel includes,
a fifth pixel connected to a third data line and the first write scan line, the third data line being connected to the third switching circuit, and
a sixth pixel connected to the third data line and the second write scan line.

10. The display device of claim 9, wherein the processing circuitry is configured to:
receive a first input image signal, a second input image signal, a third input image signal, a fourth input image signal, a fifth input image signal and a sixth input image signal respectively applied to the first pixel, the second pixel, the third pixel, the fourth pixel, the fifth pixel and the sixth pixel; and
compensate for the first input image signal, the second input image signal, the third input image signal, the fourth input image signal, the fifth input image signal and the sixth input image signal using a first compensating value, a second compensating value, a third compensating value and a fourth compensating value to respectively obtain a first intermediate image signal, a second intermediate image signal, a third intermediate image signal, a fourth intermediate image signal, a fifth intermediate image signal and a sixth intermediate image signal, the first compensating value being based on the difference in luminance between the first pixel and the second pixel, the second compensating value being based on the difference in luminance between the third pixel and the fourth pixel, the third compensating value being based on a difference in luminance between the first pixel and the fifth pixel, and the fourth compensating value being based on a difference in luminance between the third pixel and the sixth pixel.

11. The display device of claim 10, wherein the processing circuitry is configured to:
compensate for the first intermediate image signal, the second intermediate image signal, the third intermediate image signal, the fourth intermediate image signal, the fifth intermediate image signal and the sixth intermediate image signal using a fifth compensating value, a sixth compensating value and a seventh compensating value to respectively obtain a first compensated image signal, a second compensated image signal, a third compensated image signal, a fourth compensated image signal, fifth compensated image signal and a sixth compensated image signal, the fifth compensating value being based on a difference in luminance between the first pixel and the third pixel, the sixth compensating value being based on a difference in luminance between the second pixel and the fourth pixel, and the seventh compensating value being based on a difference in luminance between the fifth pixel and the sixth pixel.

12. A display device comprising:
a driving controller configured to receive input image signals and compensate the input image signals to obtain compensated image signals;
a selecting circuit including a first switching circuit activated in response to a first selecting signal and a second switching circuit activated in response to a second selecting signal; and
a display panel configured to display an image, the display panel including,
a first pixel connected to a first data line and a first write scan line, the first data line being connected to the first switching circuit,
a second pixel connected to a second data line and the first write scan line, the second data line being connected to the second switching circuit,
a third pixel connected to the first data line and a second write scan line, the second write scan line being adjacent to the first write scan line, and
a fourth pixel connected to the second data line and the second write scan line,
wherein the driving controller includes processing circuitry configured to configured to generate the compensated image signals using a difference in luminance between one reference pixel and remaining pixels, the one reference pixel being selected from among the first pixel, the second pixel, the third pixel and the fourth pixel, and the remaining pixels being among the first pixel, the second pixel, the third pixel and the fourth pixel.

13. The display device of claim 12, wherein the processing circuitry is configured to:
receive a first input image signal, a second input image signal, a third input image signal and a fourth input image signal respectively applied to the first pixel, the second pixel, the third pixel and the fourth pixel;
select the first pixel as the one reference pixel; and
compensate for the first input image signal, the second input image signal, the third input image signal and the fourth input image signal using a first compensating value, a second compensating value and a third compensating value to respectively obtain a first compensated image signal, a second compensated image signal, a third compensated image signal and a fourth compensated image signal, the first compensating value being based on a difference in luminance between the first pixel and the second pixel, the second compensating value being based on a difference in luminance between the first pixel and the third pixel, and the third compensating value being based on a difference in luminance between the first pixel and the fourth pixel.

14. The display device of claim 13, wherein further comprising:
a first lookup table configured to store the first compensating value;
a second lookup table configured to store the second compensating value; and
a third lookup table configured to store the third compensating value.

15. The display device of claim 12, wherein
the first write scan line receives a first write scan signal having a (1-1)-th activation period overlapped with a first horizontal scan period;
the second write scan line receives a second write scan signal having a (1-2)-th activation period overlapped with a second horizontal scan period;
the first selecting signal is activated during a first selecting period of each of the first horizontal scan period and the second horizontal scan period; and
the second selecting signal is activated during a second selecting period of each of the first horizontal scan period and the second horizontal scan period.

16. The display device of claim 15, wherein
the first pixel and the second pixel are connected to a first compensating scan line;
the third pixel and the fourth pixel are connected to a second compensating scan line; and
a common compensating scan signal commonly applied to the first compensating scan line and the second compensating scan line includes a common activation period overlapped with the first horizontal scan period and the second horizontal scan period.

17. The display device of claim 12, wherein the first pixel, the second pixel, the third pixel and the fourth pixel express a same color.

18. The display device of claim 12, wherein
the selecting circuit includes a third switching circuit activated in response to a third selecting signal; and
the display panel includes,
a fifth pixel connected to a third data line and the first write scan line, the third data line being connected to the third switching circuit, and
a sixth pixel connected to the third data line and the second write scan line.

19. The display device of claim 18, wherein the processing circuitry is configured to:
receive a first input image signal, a second input image signal, a third input image signal, a fourth input image signal, a fifth input image signal and a sixth input image signal respectively applied to the first pixel, the second pixel, the third pixel, the fourth pixel, the fifth pixel and the sixth pixel;
select the first pixel as the one reference pixel; and
compensate for the first input image signal, the second input image signal, the third input image signal, the fourth input image signal, the fifth input image signal and the sixth input image signal using a first compensating value, a second compensating value, a third compensating value, a fourth compensated value and a fifth compensated value to respectively obtain a first compensated image signal, a second compensated image signal, a third compensated image signal, a fourth compensated image signal, a fifth compensated image signal and a sixth compensated image signal, the first compensating value being based on a difference in luminance between the first pixel and the second pixel, the second compensating value being based on a difference in luminance between the first pixel and the third pixel, the third compensating value being based on a difference in luminance between the first pixel and the fourth pixel, the fourth compensated value being based on a difference in luminance between the first pixel and the fifth pixel, and the fifth compensated value being based on a difference in luminance between the first pixel and the sixth pixel.

20. An electronic apparatus comprising:
a processor;
a driving controller configured to receive input image signals from the processor and compensate the input image signals to obtain compensated image signals;
a selecting circuit including a first switching circuit activated in response to a first selecting signal and a second switching circuit activated in response to a second selecting signal; and
a display panel configured to display an image, the display panel including,
a first pixel connected to a first data line and a first write scan line, the first data line being connected to the first switching circuit,
a second pixel connected to a second data line and the first write scan line, the second data line being connected to the second switching circuit,
a third pixel connected to the first data line and a second write scan line, the second write scan line being adjacent to the first write scan line, and
a fourth pixel connected to the second data line and the second write scan line, wherein the driving controller includes processing circuitry configured to,
compensate for a difference in luminance between the first pixel and the second pixel,
compensate for a difference in luminance between the third pixel and the fourth pixel,
compensate for a difference in luminance between the first pixel and the third pixel, and
compensate for a difference in luminance between the second pixel and the fourth pixel.
